(19) United States
(12) Patent Application Publication
(10) Pub. No.: US 2021/0004879 A1
(43) Pub. Date: Jan. 7, 2021

(54) BATTERY

(71) Applicant: HONDA MOTOR CO.,LTD., Tokyo (JP)

(72) Inventors: Yoshihiro NAKAJIMA, Tokyo (JP); Shunichi HAGIYA, Tokyo (JP)

(21) Appl. No.: 17/023,402

(22) Filed: Sep. 17, 2020

Related U.S. Application Data
(63) Continuation of application No. PCT/JP2019/009852, filed on Mar. 12, 2019.

(30) Foreign Application Priority Data
Mar. 20, 2018 (JP) 2018-053009

(51) Int. Cl. G06Q 30/02; H01M 10/48; H01M 10/42; B60L 53/80; B60L 58/16; G01R 31/392; G01R 31/36; G01R 31/00

(52) U.S. Cl. CPC G06Q 30/0283; H01M 10/488; H01M 10/425; B60L 53/80; H01M 2220/20; G01R 31/392; G01R 31/3648; G01R 31/007; B60L 58/16

(57) ABSTRACT

A battery detachable to an electrically driven vehicle includes a deterioration displaying section which displays, visibly to an outside, a deterioration degree indicating a degree of deterioration of the battery at a present time regardless of the charge amount of the battery at a present time.

The contents of the following Japanese patent applications are incorporated herein by reference:

NO. 2018-053009 filed in JP on Mar. 20, 2018

NO. PCT/JP2019/009852 filed on Mar. 12, 2019

### BACKGROUND

### 1. Technical Field

The present invention relates to a battery.

### 2. Related Art

There is known a battery pack which includes a remaining capacity displaying section and, when fully charged, enables a degree of deterioration to be judged based on the number of LED lighting up (see, for example, Patent document 1), wherein the remaining capacity displaying section includes four LEDs which selectively light up depending on the absolute charge rate.

### PRIOR ART DOCUMENT

### Patent Document

[Patent document 1] Japanese Unexamined Patent Application Publication No. 2012-239357

### Problems to be Solved

However, since the above-mentioned battery pack needs to be fully charged to enable the degree of deterioration to be judged, the battery pack which is not fully charged cannot enable the degree of deterioration to be judged.

### General Disclose

In one aspect of the present invention, a battery is provided. The battery may be detachable to an electrically driven vehicle. The battery may include a deterioration displaying section which displays, visibly to an outside, a deterioration degree indicating a degree of deterioration of a battery at a present time regardless of the charge amount of the battery at a present time.

The deterioration displaying section may display, visibly from an outside, a deterioration class indicating a deterioration degree of the battery at a present time in a stepwise manner. The battery may further includes a storage section which stores usage history information indicating how the battery has been used in the vehicle and further stores a deterioration class condition to judge a deterioration class of the battery based on a deterioration degree of the battery. The battery may further include a calculating section which calculates a deterioration degree of the battery based on the usage history information stored in the storage section, judges a deterioration class of the battery based on the calculated deterioration degree of the battery in reference to the deterioration class condition, and outputs it to the deterioration displaying section. The usage history information may include at least any of driving history information indicating a driving history of the vehicle and usage situation history information indicating a history of usage situation of the battery.

The battery may further include a storage section which stores usage history information indicating how the battery has been used in the vehicle and further stores a price condition to judge a price of the battery based on a deterioration degree of the battery. The battery may further include a calculating section which calculates a deterioration degree of the battery based on the usage history information stored in the storage section, judges a price of the battery based on the calculated deterioration degree of the battery in reference to the price condition, and outputs it to the deterioration displaying section. The deterioration displaying section may display, visibly to an outside, a price of the battery calculated by the calculating section.

The storage section may store a price condition to judge a price of a battery based on at least one of a deterioration degree of the battery and a deterioration class of the battery. The calculating section may judge a price of the battery based on at least one of the deterioration degree of the battery and the deterioration class of the battery in reference to the price condition, and output it to the deterioration displaying section. The deterioration displaying section may display, visibly to an outside, a price of the battery calculated by the calculating section.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic diagram of a management system 20 according to the first embodiment.

FIG. 2 is a block diagram of a vehicle 100 according to the first embodiment.

FIG. 3 is a block diagram of a battery 200 according to the first embodiment.

FIG. 4 is a diagram of a table stored in the battery 200 according to the first embodiment.

FIG. 5 is a diagram of a table stored in the battery 200 according to the first embodiment.

FIG. 6 is a block diagram of a station 300 according to the first embodiment.

FIG. 7 is a block diagram of a management device 400 according to the first embodiment.

FIG. 8 is a block diagram of a server 500 according to the first embodiment.

FIG. 9 is a flow diagram according to the first embodiment.

FIG. 10 is a flow diagram of another operation according to the first embodiment.

FIG. 11 is a flow diagram of further another operation according to the first embodiment.

FIG. 12 is a flow diagram according to the second embodiment.

FIG. 13 is a block diagram of a management device 600 according to the third embodiment.

FIG. 14 is a block diagram of a server 700 according to the third embodiment.

FIG. 15 is a flow diagram according to the third embodiment.

FIG. 16 is a flow diagram of another operation according to the third embodiment.

FIG. 17 is a block diagram of a battery 800 according to the fourth embodiment.

FIG. 18 is a block diagram of a management device 900 according to the fourth embodiment.

FIG. 19 is a flow diagram according to the fourth embodiment.

FIG. 20 is a schematic diagram of a management system 19 according to the fifth embodiment.

FIG. 21 is a block diagram of a vehicle 150 according to the fifth embodiment.

FIG. 22 is a block diagram of a battery 250 according to the fifth embodiment.

FIG. 23 is a block diagram of a management device 450 according to the fifth embodiment.

FIG. 24 is a flow diagram according to the fifth embodiment.

FIG. 25 is a schematic diagram of a management system 21 according to the sixth embodiment.

FIG. 26 is a block diagram of a vehicle 160 according to the sixth embodiment.

FIG. 27 is a block diagram of a management device 600 according to the sixth embodiment.

FIG. 28 is a flow diagram according to the sixth embodiment.

FIG. 29 is a block diagram of a management device 470 according to the seventh embodiment.

FIG. 30 is a flow diagram according to the seventh embodiment.

FIG. 31 is a schematic view of a station 1000 as a variant.

FIG. 32 is a diagram which shows an example of a computer 1200 in which a plurality of aspects of the present invention is wholly or partially embodied.

### DESCRIPTION OF EXEMPLARY EMBODIMENTS

Hereinbelow, the present invention will be described through embodiments of the invention, but the following embodiments do not limit the invention disclosed in claims. In addition, not all combinations of features described in the embodiments necessarily have to be essential to solving means of the invention. Identical or similar portions in figures are given identical reference numbers, and the same explanation is omitted in some cases.

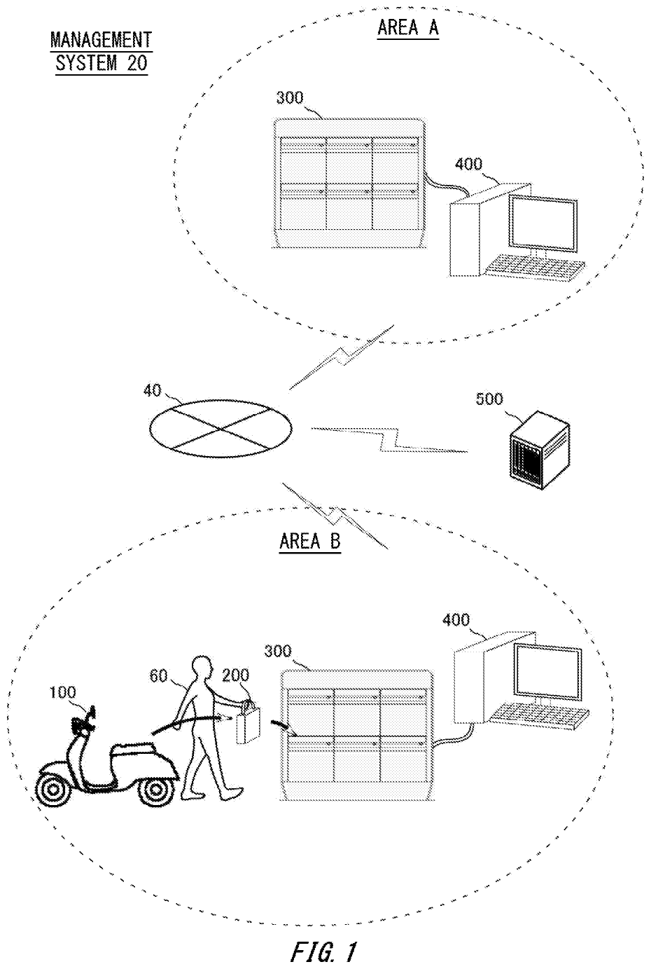

FIG. 1 is a schematic diagram of the management system 20 according to the first embodiment. The management system 20 includes the vehicle 100 which is driven by the electricity from the battery 200, the battery 200 which is detachable to the vehicle 100, and the station 300 which accommodates and charges/discharges a plurality of batteries 200. The management system 20 further includes the management device 400 to manage the battery 200, and the server 500 to communicate with the management device 400 via a communication network 40. The communication network 40 may be wired or wireless.

It is noted that the management system 20 may be a system that does not include the server 500, and does not utilize the communication network 40. In this case, the station 300 and the management device 400 may manage the lending of the battery 200 on a stand-alone basis.

In the example of FIG. 1, there are area A and area B, each of which having at least one station 300 and management device 400 disposed therein. The area A and area B are one example of a predetermined area and are areas within a circle which has the center at, for example, the station 300 and has a radius of 2 km, 5 km, 10 km, or the like.

The station 300 accommodates and charges the battery 200 used for the vehicle 100. Furthermore, the station 300 lends the battery 200 to a user 60 of the vehicle 100.

The management device 400 is, for example, a PC, and is disposed at the station 300 or manages the station 300 remotely. Specifically, the management device 400 controls the charging and lending of the battery 200 accommodated in the station 300. The management device 400 obtains the information of the vehicle 100 via the battery 200 and the station 300. Furthermore, the management device 400 transmits the information obtained from the battery 200 via the station 300 to the server 500.

In the present embodiment, the vehicle 100 is a two-wheeled motor vehicle. Additionally or alternatively, the vehicle 100 may be a four-wheeled motor vehicle, an electrical bicycle, or the like.

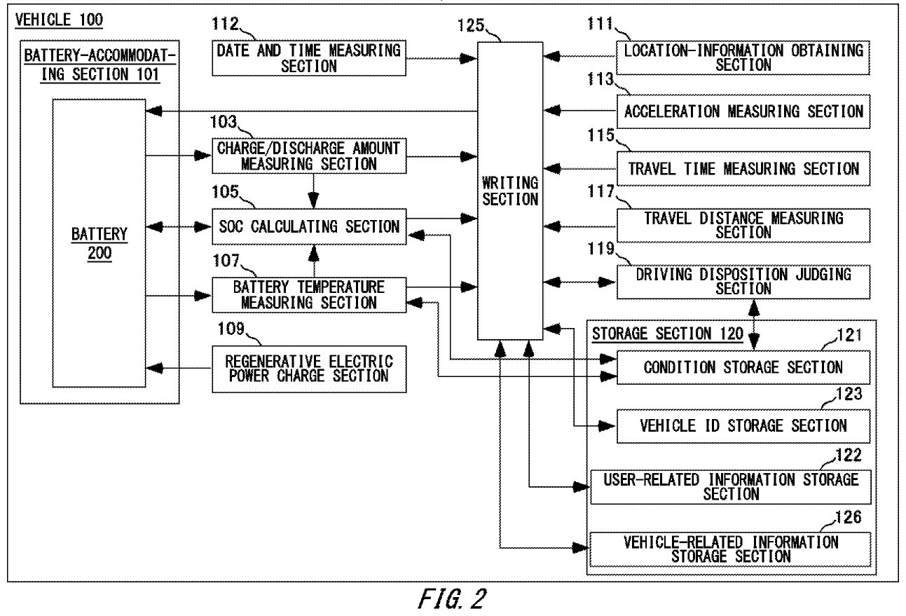

FIG. 2 is a block diagram of the vehicle 100. The vehicle 100 includes a battery-accommodating section 101 to accommodate the battery 200, and a storage section 120 including a condition storage section 121, a user-related information storage section 122, a vehicle-related information storage section 126, and a vehicle ID storage section 123. The battery-accommodating section 101 accommodates the battery 200 and is electrically connected thereto.

The condition storage section 121 stores driving disposition judging condition to judge driving disposition of the user 60 of the vehicle 100, a SOC (State of Charge) condition within an appropriate range for the battery 200, and a temperature condition within an appropriate range for the battery 200. The SOC condition within an appropriate range includes that the SOC is not below a predetermined appropriate lower limit SOC. The temperature condition within an appropriate range includes the temperature being not above a predetermined appropriate upper limit temperature and not below a predetermined appropriate lower limit temperature.

The vehicle ID storage section 123 stores a vehicle ID to identify the individual of the vehicle 100. The vehicle ID includes, for example, VIN (Vehicle Identification Number).

The user-related information storage section 122 stores the user-related information which relates to the user 60 who uses the vehicle 100. The vehicle-related information storage section 126 stores the vehicle-related information which relates to the vehicle 100.

The vehicle-related information includes a vehicle ID, vehicle class information indicating the vehicle class of the vehicle 100, home base location information indicating the location of the home base in which the vehicle 100 is used, at least the most recent path history information, or the like. The user-related information includes a user ID, user address information indicating the user address of the user 60, or the like.

The vehicle 100 further includes a writing section 125 to write, to the battery 200, a plurality of pieces of information input from each component of the vehicle 100, as well as the vehicle ID stored in the vehicle ID storage section 123, the user-related information stored in the user-related information storage section 122, and the vehicle-related information stored in the vehicle-related information storage section 126.

The vehicle 100 further includes a charge/discharge amount measuring section 103 to measure the charge/discharge amount for the battery 200 accommodated in the battery-accommodating section 101 and output it to the writing section 125, and a SOC calculating section 105 to calculate the SOC and output it to the writing section 125. The vehicle 100 further includes a battery temperature measuring section 107 to measure the temperature for the battery 200 accommodated in the battery-accommodating section 101 to judge whether the temperature is within an appropriate range and output the result to the writing section 125, and the regenerative electric power charge section 109 to charge the battery 200 with the regenerative electric power generated by the vehicle 100. Both of the charge/discharge amount measuring section 103 and the battery temperature measuring section 107 also output the measurement data to the SOC calculating section 105. It is noted that the battery temperature measuring section 107 may output the measured temperature itself to the writing section 125.

The charge/discharge amount measuring section 103 measures the current flowing to/from the battery 200 and the voltage of the battery 200 and integrates the current and the voltage to calculate the power amount. When regenerative electric power is generated by the brake operation of the vehicle 100, the regenerative electric power charge section 109 charges the battery 200 with the generated electrical power. The battery temperature measuring section 107 measures the temperature of the battery 200 and refers to the condition storage section 121 to calculate the number of times that the temperature of the battery 200 becomes equal to or above a predetermined appropriate upper limit temperature and the number of times that the temperature of the battery 200 becomes equal to or below a predetermined appropriate lower limit temperature.

The SOC calculating section 105 calculates the SOC of the battery 200 when it receives the voltage of the battery 200 from the charge/discharge amount measuring section 103 and receives the temperature of the battery 200 from the battery temperature measuring section 107.

More specifically, assuming that measured data such as a premeasured no-load discharge property (OCV [Open Circuit Voltage]) of the battery 200, a temperature characteristic, and a SOC-OCV curve of the battery 200 premeasured under a particular condition is written to the battery 200 as a reference, the SOC calculating section 105 reads the measured data written to the battery 200. The SOC calculating section 105 continuously captures the impedance of the battery 200 in the impedance-track manner by using the voltage and temperature of the battery 200 received from the charge/discharge amount measuring section 103 and the battery temperature measuring section 107 and the measured data read from the battery 200 and writes it to the battery 200 to update the SOC-OCV curve read from the battery 200. The SOC calculating section 105 calculates the current SOC of the battery 200 based on the updated SOC-OCV curve and the current voltage of the battery 200 received from the charge/discharge amount measuring section 103 and outputs it to the writing section 125. The SOC calculating section 105 also refers to the condition storage section 121 to judge whether the SOC of the battery 200 during a mount period, which is a period from the moment when the battery 200 is mounted to the vehicle 100 and to the moment when it is removed, is within an appropriate range and outputs the result to the writing section 125.

The vehicle 100 further includes a date and time measuring section 112 to measure the current date and time and output them to the writing section 125, a location-information obtaining section 111 to obtain the current location information of the vehicle 100 and output it to the writing section 125, and an acceleration measuring section 113 to measure the acceleration of the vehicle 100 and output it to the writing section 125.

The location-information obtaining section 111 obtains GPS data representing longitude and latitude of the location of the vehicle 100 from, for example, the GPS (Global Positioning System) and outputs the above-mentioned area including the location of the vehicle 100 indicated by the GPS data, for example, area A, area B, and the like, as the current location information of the vehicle 100. In addition, the location-information obtaining section 111 outputs the obtained GPS data itself as the current location information of the vehicle 100.

The date and time measuring section 112 measures and outputs the time slot and a day of the week of one drive cycle, which is, for example, from the moment when the ignition switch of the vehicle 100 is turned on to the moment when it is turned off.

The vehicle 100 further includes a travel time measuring section 115 to measure a continuous travel time per one drive cycle of the vehicle 100 and output it to the writing section 125 and a travel distance measuring section 117 to measure a continuous travel distance per one drive cycle of the vehicle 100 and output it to the writing section 125.

The vehicle 100 further includes a driving disposition judging section 119 to judge the driving disposition of the user 60 of the vehicle 100 based on the information received from the writing section 125 and the driving disposition judging condition stored in the condition storage section 121 and output the result to the writing section 125.

The driving disposition judging condition is a condition according to which, for example, the driving disposition is judged as acceleration-oriented disposition when the number of times that the acceleration of the vehicle 100 becomes equal to or higher than a predetermined threshold is equal to or more than a predetermined number of times, and is judged as energy saving-oriented disposition when the number of times is less than a predetermined number of times. Herein, the predetermined number of times is, for example, a value proportional to the accumulated travel distance which is the accumulation of the continuous travel distance of the vehicle 100, or the accumulated travel time which is the accumulation of the continuous travel time, and increases as the accumulated travel distance or the accumulated travel time of the vehicle 100 increases. Alternatively, the driving disposition judging condition may be a condition according to which the driving disposition is judged as acceleration-oriented disposition when the ratio of the number of times that the acceleration of the vehicle 100 becomes equal to or higher than a predetermined threshold to the accumulated travel distance or accumulated travel time of the vehicle 100 is equal to or more than a predetermined threshold, and is judged as energy saving-oriented disposition when the ratio is less than the predetermined threshold.

The driving disposition judging condition may also be a condition according to which, for example, the driving disposition is judged as long distance-oriented driving disposition or long time-oriented driving disposition and is judged as short distance-oriented driving disposition or short time-oriented driving disposition when the continuous travel distance or continuous travel time of the vehicle 100 is equal to or more than a predetermined threshold and when it is less than a predetermined threshold, respectively.

It is noted that the vehicle 100 may communicate with any or both of the management device 400 and the server 500 via the communication network 40.

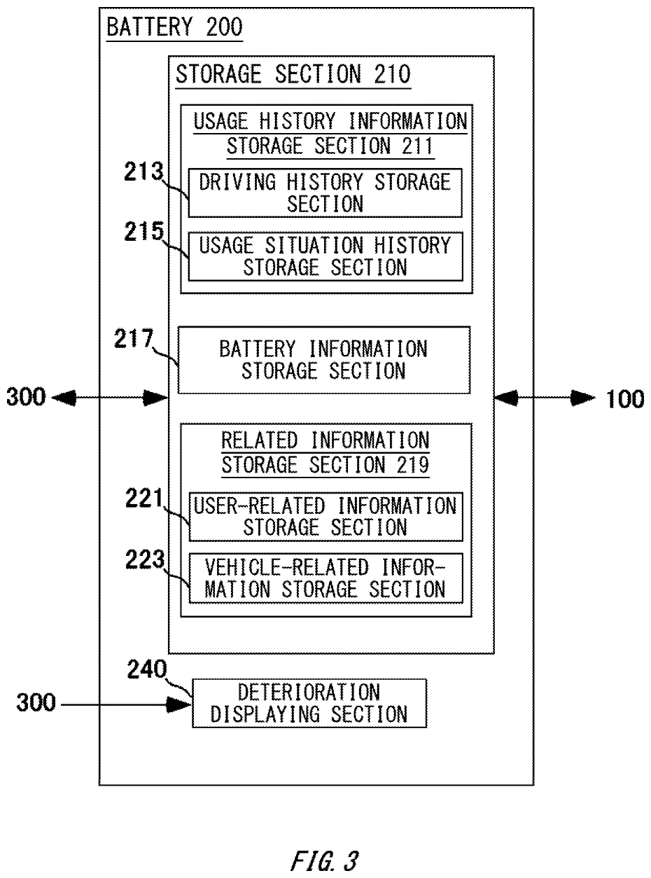

FIG. 3 is a block diagram of the battery 200. The battery 200 is a so-called mobile battery, which can be carried by the user 60 after it is removed from the vehicle 100. The battery 200 supplies electrical power to the vehicle 100 when it is mounted to the vehicle 100.

The battery 200 includes, for example, a storage section 210 to store a plurality of pieces of information received from the vehicle 100 and a deterioration displaying section 240 to display the current deterioration state of the battery 200.

The storage section 210 includes a usage history information storage section 211 to store the usage history information of the battery 200 used in the vehicle 100, a battery information storage section 217 to store the battery information related to the battery 200, and a related information storage section 219 to store the related information of the battery 200 used in the vehicle 100.

The usage history information indicates the manner in which the battery 200 has been used in the vehicle 100 during the mount period of the battery 200. The usage history information includes driving history information indicating the driving history of the vehicle 100 and usage situation history information indicating the history of usage situation of the battery 200.

The usage history information storage section 211 includes a driving history storage section 213 to store the driving history information of the vehicle 100 and a usage situation history storage section 215 to store the usage situation history information of the battery 200.

The driving history information includes, for example, path history information indicating a history of the path along which the vehicle 100 travelled during the mount period of the battery 200. In addition, the driving history information includes, for example, history information such as a continuous travel distance, a continuous travel time, a number of sudden accelerations and decelerations, a travel time slot, a travel day of the week, and a travel area per one drive cycle of the vehicle 100 during the mount period of the battery 200, as well as an accumulated travel distance, an accumulated travel time, or the like of all drive cycles during the mount period of the battery 200. In addition, the driving history information includes, for example, the driving disposition, which indicates the manner in which the vehicle 100 is driven during the mount period of the battery 200. The driving disposition includes, for example, as described above, the acceleration-oriented disposition, energy saving-oriented disposition, long distance-oriented driving disposition, long time-oriented driving disposition, short distance-oriented driving disposition, short time-oriented driving disposition, or the like.

The usage situation history information includes, for example, the history information such as the SOC, charge amount, and discharge amount of the battery 200, the number of times that the temperature of the battery 200 becomes equal to or more than a predetermined appropriate upper limit temperature, or the number of times that the temperature of the battery 200 becomes a predetermined appropriate lower limit temperature during the mount period of the battery 200. The usage situation history information may include the information indicating whether the SOC of the battery 200 during the mount period of the battery 200 is within the appropriate range and the information is judged and written by the vehicle 100 as described above.

The usage situation history information may include the temperature history itself of the battery 200 during the mount period of the battery 200. In addition, the usage situation history information may include not only the information which relates to the travel of the vehicle 100 during the mount period of the battery 200, but also the information which does not relate to the travel of the vehicle 100 during the period, for example, the information due to the self-discharge and the aging deterioration of the battery 200, or the like. In addition, the usage situation history information may include the information during the mount period of the battery 200, such as deterioration degree (SOH [State of Health]) indicating the degree of deterioration of the battery 200, the deterioration class indicating the deterioration degree in a stepwise manner, and the change of the deterioration class, and the information is judged and written by the management device 400. Alternatively, the information of the deterioration degree may be calculated by the vehicle 100 during the travel of the vehicle 100. Herein, the deterioration degree (SOH) of the battery 200 is represented as a remained capacity ratio, that is, the ratio as a percentage of the capacity of the battery 200 in the current state of the battery 200 to the capacity of the battery 200 in the unused state of the battery 200. The deterioration degree (SOH) can also be defined as a value of the ratio of the current capacity to the nominal capacitance of the battery 200, represented as a percentage.

In addition, the usage situation history information may include the information indicating whether the deterioration degree of the battery 200 during the mount period of the battery 200 is within the appropriate range, and the information is judged and is written by the management device 400.

The battery information stored in the battery information storage section 217 includes the battery ID to identify the individual of the battery 200. In addition, the information of the SOC of the battery 200 stored in the usage situation history storage section 215 and the information of the current deterioration degree of the battery 200 are used as battery information.

The battery information further includes the measured data such as premeasured no-load discharge property (OCV) of the battery 200, the temperature characteristic, and the SOC-OCV curve of the battery 200 which is premeasured under a particular condition. The battery information may also include the nominal capacitance of the battery 200 which is measured under a particular condition. In addition, the battery information may further include the information of a type of the battery 200, and the information of the current maximum allowable current of the battery 200, maximum allowable voltage, and maximum allowable temperature, or the like. The information such as the current maximum allowable current, maximum allowable voltage and maximum allowable temperature of the battery 200 is preferably measured by the vehicle 100 during the travel of the vehicle 100.

The related information storage section 219 includes a user-related information storage section 221 to store the user-related information related to the user 60 who uses the vehicle 100 with the battery 200 mounted, and a vehicle-related information storage section 223 to store the vehicle-related information related to the vehicle 100 with the battery 200 mounted. The user-related information and the vehicle-related information are written by the vehicle 100. The above-mentioned path history information may be stored in both of the vehicle-related information storage section 223 and the usage history information storage section 211, or may be stored in any one of them.

The deterioration displaying section 240 displays, visibly to the outside, the current deterioration degree or deterioration class of the battery 200 regardless of the current charge amount, that is, the remaining power amount of the battery 200. For example, the deterioration displaying section 240 may have one or more LEDs and display the current deterioration degree or deterioration class of the battery 200 by changing the display color, the number of lighting or the like of the LED. In addition, the deterioration displaying section 240 may display the current deterioration degree or deterioration class of the battery 200 by means of the attached label with a color which is different depending on, for example, the deterioration degree or deterioration class.

Since the deterioration displaying section 240 displays, visibly to the outside, the deterioration degree or the like regardless of the remaining power amount, the degree of the deterioration can be easily judged even in a non-fully charged state.

It is noted that the battery 200 may communicate with either or both of the management device 400 and the server 500 via the communication network 40.

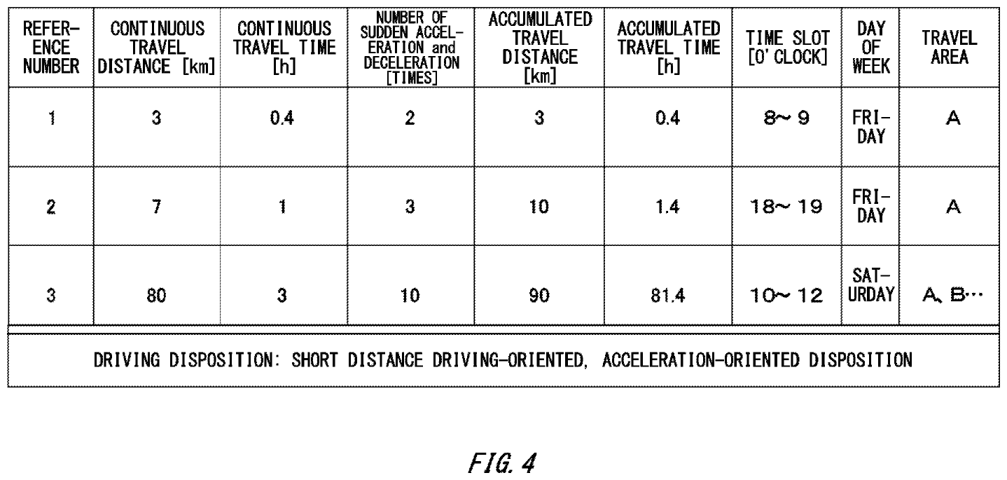

FIG. 4 is one example of the table of the driving information history information stored in the driving history storage section 213. In this table, “reference number”, “continuous travel distance [km]”, “continuous travel time [h]”, “number of sudden accelerations and decelerations [number of times]”, “accumulated travel distance [km]”, “accumulated travel time [h]”, “time slot [o'clock]”, “day of the week”, and “travel area” are recorded in association with each other. The table is recorded per user ID (or vehicle ID) and the “driving disposition” is recorded per table.

For example, in the row of reference number 1, the continuous travel distance is recorded as 3 km, the continuous travel time as 0.4 h, the number of sudden accelerations and decelerations as twice, the accumulated travel distance as 3 km, the accumulated travel time as 0.4 h, the time slot as 8-9 o'clock, the day of the week as Friday, and the travel area as A. Furthermore, a result is stored in which the driving disposition of the user 60 who borrows the battery 200 and uses the vehicle 100 is judged as the short distance-oriented driving disposition and acceleration-oriented disposition based on the driving history data the three drive cycles from reference number 1 to 3.

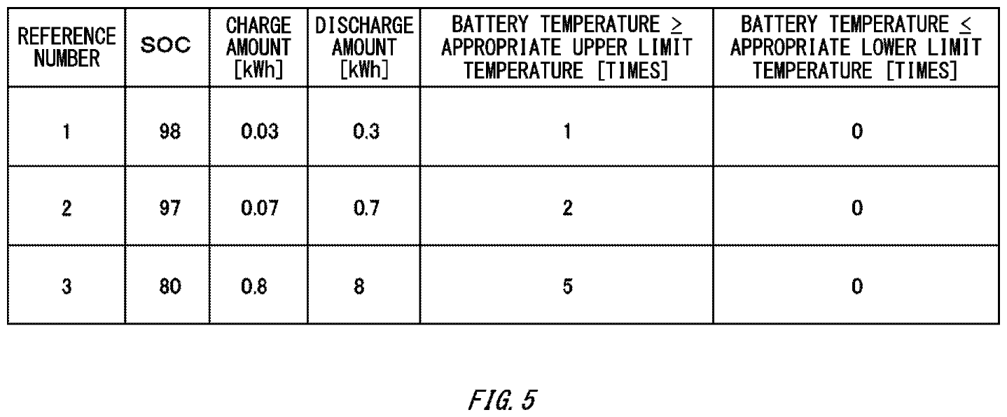

FIG. 5 shows one example of a table of the usage situation history information stored in the usage situation history storage section 215. In this table, “reference number”, “SOC”, “charge amount [kWh]”, “discharge amount [kWh]”, “battery temperature≥appropriate upper limit temperature [number of times]”, and “battery temperature≤appropriate lower limit temperature [number of times]” are recorded in association with each other.

For example, in the row of reference number 1, the SOC is recorded as 98, the charge amount as 0.03 kWh, the discharge amount as 0.3 kWh, the number of times that the battery temperature becomes equal to or higher than the appropriate upper limit temperature as one, and the number of times that the battery temperature becomes equal to or lower than the appropriate lower limit temperature as zero. It is noted that the reference numbers described at the left ends of each table in FIG. 4 and FIG. 5 correspond with each other. That is, the data indicated by the same reference numbers are the data in the same one drive cycle.

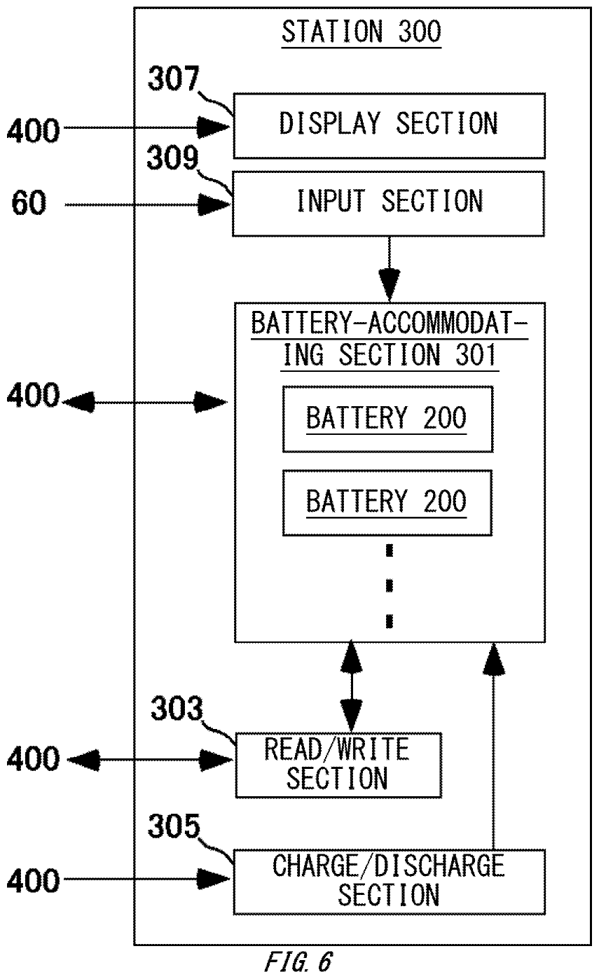

FIG. 6 is a block diagram of the station 300. The station 300 includes a battery-accommodating section 301 to accommodate a plurality of batteries 200, a read/write section 303 to perform read and write on the plurality of batteries 200 accommodated in the battery-accommodating section 301, and the charge/discharge section 305 to control the charge/discharge according to the instruction from the management device 400.

Once accommodating the battery 200, the battery-accommodating section 301 retains the battery 200 such that it is electrically connected to the battery 200. As shown in FIG. 1 as an example, the battery-accommodating section 301 of the station 300 may be a return slot with a plurality of covers arranged in a matrix having four rows and four columns. In this case, by closing and locking the cover after accommodating one battery, each return slot may prohibit the accommodated battery 200 to be taken out from the outside. It is noted that, hereinafter, the return slot of the battery-accommodating section 301 may be referred to as an accommodating location.

In the battery-accommodating section 301, the accommodating location of the battery 200 varies depending on the deterioration class of the battery 200. In the battery-accommodating section 301, the accommodating location of the battery 200 may vary depending on the deterioration degree, the model number, the type, the performance, or the like of the battery 200. Herein, the model number of the battery 200 includes, for example, the manufacturer name of the battery 200, and a type such as a two-wheeled motor vehicle type and a four-wheeled motor vehicle type. In addition, the type of the battery 200 includes, for example, all solid battery, lithium ion battery, or the like. In addition, the performance of the battery 200 includes, for example, high output and short life, low output long life, or the like.

In the station 300 of FIG. 1, in the battery-accommodating section 301, the row of the accommodating location of the battery 200 varies depending on the deterioration class. For example, specifically, the first row from the top in the document is dedicated to the battery 200 of deterioration class 1 or 2, the second row from the top is dedicated to the battery 200 of deterioration class 3, the third row from the top is dedicated to the battery 200 of deterioration class 4, and the fourth row from the top is dedicated to the battery 200 of deterioration class 5.

Based on the instruction from the management device 400, the battery-accommodating section 301 enables an accommodated particular battery 200 to be taken out from the outside so that the battery can be lent. In addition to enabling the battery 200 to be taken out from the outside, the battery-accommodating section 301 may, for example, flash LED which is provided in the accommodating location such that the accommodating location of the battery 200 can be easily identified from the outside.

Upon detecting that the battery 200 has been returned to a particular accommodating location, the battery-accommodating section 301 outputs the information of the particular accommodating location to the management device 400.

Upon detecting that the battery 200 has been accommodated in the battery-accommodating section 301, the read/write section 303 reads the information of the battery 200 and outputs it to the management device 400. In addition, the read/write section 303 writes the information received from the management device 400 to the battery 200 based on the instruction from the management device 400.

The station 300 further includes a display section 307 to display the information received from the management device 400 and an input section 309 to accept the input from the user 60. The display section 307 and the input section 309 may be an integrated touch panel. In addition, the input section 309 may be a push button disposed independently of the display section 307.

The display section 307 displays the reward information received from the management device 400. For example, the display section 307 may display a barcode for a communication terminal of the user 60 to read, and thereby cause the reward information to be displayed on the communication terminal. Instead of or in addition to the display section 307, the station 300 may include a print section configured to print and eject document on which the reward information is described based on the instruction from the management device 400.

The display section 307 may display a list of, for example, the deterioration class and price of a plurality of batteries 200 to the user 60 who has returned the battery 200. The display section 307 may visually inform the user 60 of the accommodating location of the battery 200 which is recommended or selected by the management device 400, for example by displaying an image of the battery-accommodating section 301 and flashing a particular accommodating location in the image.

The input section 309 outputs, to the management device 400, the information received from the user 60 who has returned the battery 200. The input section 309 may make a particular battery 200 accommodated in the battery-accommodating section 301 lendable based on the input from the user 60 who has returned the battery 200.

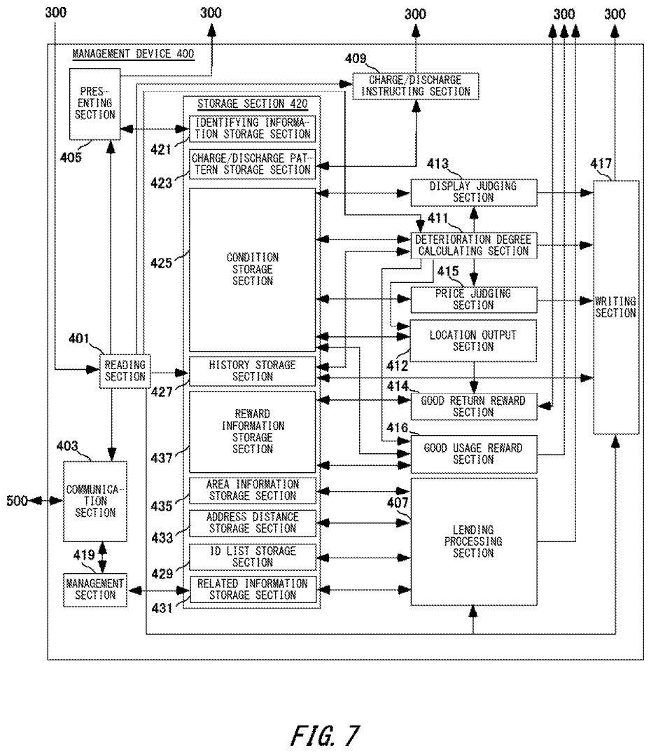

FIG. 7 is a block diagram of the management device 400. The management device 400 includes a reading section 401 to read the information of the battery 200 from the battery 200 stocked in the station 300, and a storage section 420 to store a plurality of pieces of information. The reading section 401 outputs, to the station 300, an instruction to read the information of the battery 200 which has been returned by the user 60.

The storage section 420 includes a identifying information storage section 421 to store identifying information to identify the battery 200 stocked in the station 300, a charge/discharge pattern storage section 423 to store the charge/discharge pattern corresponding to the battery information, and a condition storage section 425 to store a plurality of judgement condition.

The identifying information storage section 421 stores the above-mentioned identifying information in association with unique information which is the information unique to the vehicle 100 and the battery 200, such as vehicle-related information and usage history information. The identifying information includes a group ID to identify the group of the battery 200, a battery ID to identify the individual of the battery 200, or the like. The group of the battery 200 is grouped based on at least any of the deterioration degree, the deterioration class, the model number, type, and the performance of the battery 200. The group ID may be information itself such as the deterioration degree or may be other symbols or character. When the identifying information storage section 421 stores the group ID instead of battery ID, the amount of stored information is reduced.

The unique information stored in the identifying information storage section 421 includes (A) the vehicle ID to identify the individual of the vehicle, (B) either of the continuous travel distance and the continuous travel time of one drive cycle during the period in which the battery is mounted to the vehicle, (C) distance information indicating whether the continuous travel distance is longer than a predetermined distance, (D) either of the total travel distance and the total travel time during a period when the motor is mounted to the vehicle, (E) the condition of the battery used in the vehicle during the period when the battery is mounted to the vehicle, such as (a) a deterioration degree indicating the degree of deterioration, (b) a change of deterioration class indicating the deterioration degree in a stepwise manner, (c) electricity consumption, (d) allowance information indicating whether the electricity consumption is within a predetermined allowable range, and (e) temperature history.

In the charge/discharge pattern stored in the charge/discharge pattern storage section 423, for example, the current value flowing into the battery 200 and the current value flowing out of the battery 200 are reduced as the deterioration degree of the battery 200 increases. In addition, in the charge/discharge pattern, for example, the charge period to reach the rated voltage of the battery 200 and the discharge period to reach a predetermined voltage are increased as the deterioration degree of the battery 200 increases. When the battery 200 is charged/discharged, the current value is preferably constant, as in, for example, CCCV (Constant Current Constant Voltage) charge, regardless of the deterioration degree of the battery 200.

It is noted that when the battery information includes the information of the type of the battery 200, the information such as the current maximum allowable current, the maximum allowable voltage, and the maximum allowable temperature of the battery 200, or the like, the charge/discharge pattern corresponds to both of these information and the deterioration degree of the battery 200, and may be further subdivided.

The condition storage section 425 stores a deterioration class condition used to judge the deterioration class which indicates the deterioration degree of the battery 200 in a stepwise manner based on the deterioration degree of the battery 200. In addition, the condition storage section 425 stores the price condition used to judge the price of the battery 200 based on the deterioration class of the battery 200. In addition, the condition storage section 425 stores the display manner condition used to judge the display manner in which the deterioration class of the battery 200 is displayed on the battery 200 visibly to the outside, based on the deterioration class of the battery 200. In addition, the condition storage section 425 stores an accommodating location condition used to judge the accommodating location in which the battery 200 should be accommodated for each deterioration class of the battery 200, based on the deterioration class of the battery 200. In addition, the condition storage section 425 stores the good usage condition for the deterioration degree of the battery 200. The condition storage section 425 further stores a deterioration degree condition within an appropriate range of the battery 200. The deterioration degree condition within an appropriate range includes that the deterioration degree is not below a predetermined appropriate lower limit deterioration degree.

The deterioration class condition is a condition according to which the value of the deterioration class decreases as the value of the deterioration degree increases. For example, as the relationship between the deterioration degree (SOH) and the deterioration class, the deterioration class is set to 1 when SOH=91 to 100, the deterioration class is set to 2 when SOH=81 to 90, the deterioration class is set to 3 when SOH=71 to 80, the deterioration class is set to 4 when SOH=61 to 70, the deterioration class is set to 5 when SOH=51 to 60, and the deterioration class is set to unusable when SOH≤50. It is noted that the management device 400 may judge that the battery 200 which is unusable is a target to be collected.

The price condition includes the condition according to which, for example, the lending price of the battery 200 increases as the deterioration class increases, assuming that the fully charged battery 200 is to be lent. For example, the condition is set such that the lending price is 5000 yen when the deterioration class is 1, the lending price is 4500 yen when the deterioration class is 2, the lending price is 4000 yen when the deterioration class is 3, the lending price is 3500 yen when the deterioration class is 4, and the lending price is 3000 yen when the deterioration class is 5.

The display manner condition includes a condition according to which, for example, as the relationship between the deterioration class and the display manner, a blue label is attached to the deterioration displaying section 240 of the battery 200 when the deterioration class is 1 to 3, and a red label is attached to the deterioration displaying section 240 of the battery 200 when the deterioration class is 4 to 5.

The accommodating location condition includes the relationship between the deterioration class and the accommodating location in which the battery 200 should be accommodated. For example, for the accommodating location, in a case of the station 300 having the battery-accommodating section 301 with four rows and four columns in FIG. 1, in the document, the first row from the top is dedicated to the battery 200 deterioration class 1 or 2, the second row from the top is dedicated to the battery 200 of deterioration class 3, the third row from the top is dedicated to the battery 200 of deterioration class 4, and the fourth row from the top is dedicated to the battery 200 of deterioration class 5.

The good usage condition is, for example, a condition according to which the use manner is judged as good when the relationship between the deterioration degree and the appropriate range meets SOH≥61 and the use manner is judged as not good when the relationship meets SOH<61. Additionally or alternatively, the good usage condition is a condition according to which, for example, the use manner is judged as good when the relationship between the change amount of the deterioration degree during the mount period of the battery 200 (SOH change amount) and the appropriate range meets SOH change amount≥10, and the use manner is judged as not good when the relationship meets SOH change amount ≥10.

The storage section 420 further includes a history storage section 427 to store the accumulated usage history information which is the information obtained by accumulating the usage history information read by the reading section 401 from the battery 200 returned to the station 300 in association with the battery ID of the battery 200. The history storage section 427 may store the vehicle ID of the vehicle 100 with the battery 200 mounted and the usage history information during the period when the battery was used in the vehicle 100 in association with the battery ID. It is noted that the accumulated usage history information herein is preferably the usage history information of all drive cycles during the period from the moment the battery 200 started to be used as a new product to the current moment, but the usage history information of some drive cycles during the period may be lacked.

The storage section 420 further includes an ID list storage section 429 to store the list of a plurality of IDs and a related information storage section 431 to store the related information of the vehicle 100 and the user 60 for which the battery 200 stocked in the station 300 can be lent.

The ID list storage section 429 stores a vehicle ID list of the vehicle ID and a user ID list of the user ID to which the stocked battery 200 can be lent. The ID list storage section 429 may further store a battery ID list of the battery ID to which the stocked battery 200 can be lent.

In the vehicle ID list stored in the ID list storage section 429, the vehicle ID of the vehicle 100 whose home base location where it is used is included within a predetermined area is listed, and the vehicle ID of the vehicle 100 whose home base location where it is used is outside the predetermined area is not listed.

In addition, in the user ID list stored in the ID list storage section 429, the user ID of the user 60 whose user address is included in a predetermined area is listed, and the user ID of the user 60 whose user address is outside the predetermined area is not listed. The predetermined area herein may include an administrative district, for example, Shinjuku, Shibuya, or the like, and may include area A or area B as shown in FIG. 1.

The related information stored in the related information storage section 431 includes, for example, the related information which is associated with the station 300, among a plurality of related information stored in the server 500.

The related information which is associated with the station 300 includes, for example, the related information of the user 60, wherein the address of the user 60 is judged to be close to the address of the station 300 according to a predetermined judgement standard.

In addition, the related information which is associated with the station 300 includes, for example, the related information of the vehicle 100, wherein the address of the station 300 is judged to be close to the location of the home base where the vehicle 100 is used in a predetermined judgement standard.

The storage section 420 further includes an address distance storage section 433 to store a predetermined address and distance, an area information storage section 435 to store the area information indicating a predetermined area, and a reward information storage section 437 to store the reward information to reward the user 60.

The predetermined address stored in the address distance storage section 433 includes, for example, the location where the station 300 exists, and the predetermined distance is, for example, 2 km, 5 km, 10 km, or the like. The predetermined area stored in the area information storage section 435 is an area which has the center at, for example, the station 300 and within a circle which has a radius of 2 km, 5 km, 10 km, or the like.

The reward information stored in the reward information storage section 437 is output to the station 300 when the user 60 returns the battery 200 to the station 300, and then the management device 400 judges that the method in which the user 60 uses the battery 200 is good or judges that the location where the battery 200 returned to the station 300 is accommodated by the user 60 is appropriate. It is noted that the reward content shown in the reward information may be any content, for example, a discount of a lending price of the battery, an award of a point which can be used to pay the lending price of the battery, an award of a product voucher in a member store, or the like. It is noted that the reward information is one example of the good return reward information and good use reward information.

The management device 400 further includes a communication section 403 to communicate with the server 500, and the management section 419 to receive, from the server 500 during the communication with the server 500, the related information of the vehicle 100 and the user 60 to which the battery 200 stocked in the station 300 can be lent, and manage it. The management device 400 further includes a charge/discharge instructing section 409 to instruct the station 300 to perform charge/discharge on a particular battery 200 stocked in the station 300, and a writing section 417 to instruct the station 300 to write information received from each component of the management device 400.

The communication section 403 receives from the server 500 the related information of the vehicle 100 and the user 60 for which the battery 200 stocked in the station 300 can be lent, and then outputs it to the management section 419.

The management section 419 receives the above-mentioned related information from the communication section 403 and then stores it in the related information storage section 219 for management. The management section 419 requests the server 500 to transmit related information via the communication section 403 at a predetermined timing, for example, at a particular time every day. The management section 419 also requests the server 500 to transmit the related information via the communication section 403 when the communication with the server 500 is interrupted and then recovered.

Upon receiving, from the reading section 401, the battery information read by the reading section 401 from the battery 200 returned by the user 60 to the station 300, the charge/discharge instructing section 409 refers to the charge/discharge pattern storage section 423, judges the charge/discharge pattern corresponding to the battery information, and outputs the instruction for the charge/discharge section 305 of the station 300. The charge/discharge instructing section 409 may instruct the discharge process of the battery 200, for example, when the charged batteries 200 stocked in the station 300 is abundant enough to afford to give electrical power to an outside electric power company.

The writing section 417 outputs the instruction to write, to the battery 200 to be lent to the user 60 among the battery 200 stocked in the station 300, the related information including vehicle-related information and user-related information read by the reading section 401 from the battery 200 returned by the user 60 to the station 300.

In addition, the writing section 417 may output the instruction to write, to the battery 200 to be lent to the user 60, the usage history information which was read by the reading section 401 from the battery 200 returned by the user 60 to the station 300 and is stored in the history storage section 427. In this case, the writing section 417 may also output the instruction to write, to the battery 200 to be lent to the user 60, the accumulated usage history information stored in the history storage section 427.

The management device 400 further includes a presenting section 405 to output, to the station 300, an instruction to present a particular battery 200 stocked in the station 300 to the user 60. The presenting section 405 presents the identifying information which identifies the battery 200 stocked in the station 300 by extracting it from the identifying information storage section 421 based on the unique information of the battery 200 used in the vehicle 100 which is read by the reading section 401. It is noted that the unique information read by the reading section 401 may not necessarily include the most recent information in the vehicle 100 or battery 200. It is noted that the presenting section 405 may, for example, have an artificial intelligence (AI) and extract the identifying information from the unique information newly read by the reading section 401 based on the learned result of the relation between the unique information and the identifying information.

The above-mentioned extracting and presenting the identifying information includes recommending one or more batteries 200 stocked in the station 300 based on the extracted identifying information. In other word, it includes identifying one or more batteries 200 stocked in the station 300 and recommend it as a candidate for exchange with the battery 200 used in the vehicle 100. The presenting section 405 may, for example, output, to the display section 307 of the station 300, the instruction to display the information of one or more recommended batteries 200.

It is noted that the battery 200 recommended by the presenting section 405 may include the charged battery 200, and insufficiently charged or completely uncharged battery 200. The case in which the insufficiently charged or completely uncharged battery 200 is recommended includes, for example, the case in which the user 60 returns sufficiently charged battery 200 to the station 300 and borrows the insufficiently charged or completely uncharged battery 200 in order to cooperate in giving electrical power to an outside electric power company from the station 300. In this case, the user 60 may, for example, mount another battery 200 to the vehicle 100 as the electrical power source of the vehicle 100, and mount the insufficiently charged or completely uncharged battery 200 to the vehicle 100 after coming home to use it as the battery 200 for storage for house power generation.

The management device 400 further includes a deterioration degree calculating section 411 to calculate the deterioration degree of the battery 200 returned to the station 300, a display judging section 413 to judge the display manner of the deterioration class in the battery 200 based on the deterioration class received from the deterioration degree calculating section 411, and a price judging section 415 to judge the price of the battery 200.

Upon receiving the battery ID read by the reading section 401, the deterioration degree calculating section 411 extracts accumulated usage history information stored in the history storage section 427 using the battery ID, and calculates and outputs the deterioration degree indicating the degree of deterioration of the battery 200 based on the extracted accumulated usage history information. It is noted that calculating the deterioration degree of the battery 200 based on the accumulated usage history information includes calculating the deterioration degree based on the accumulated driving history information and calculating the deterioration degree based on the accumulated usage situation history information of the battery 200.

The deterioration degree calculating section 411 refers to the deterioration class condition stored in the condition storage section 425 to judge the deterioration class of the battery 200 based on the calculated deterioration degree of the battery 200 and output it to the display judging section 413, the price judging section 415, and the writing section 417. The deterioration degree calculating section 411 further judges the change of the deterioration class of the battery 200 and outputs the result to the writing section 417. The deterioration degree calculating section 411 further refers to the condition storage section 425 to judge whether the deterioration degree of the battery 200 during the mount period of the battery 200 is within an appropriate range and output it to the writing section 417.

Upon receiving the deterioration class of the battery 200 from the deterioration degree calculating section 411, the display judging section 413 refers to the display manner condition stored in the condition storage section 425 to judge the display manner of the battery 200 based on the deterioration class and output it to the writing section 417.

Upon receiving the deterioration class of the battery 200 from the deterioration degree calculating section 411, the price judging section 415 refers to the price condition stored in the condition storage section 425 to judge the price of the battery 200 based on the deterioration class and output it to the writing section 417.

The management device 400 further includes a location output section 412 to judge the appropriate return location of the battery 200 based on the deterioration class received from the deterioration degree calculating section 411 and output the accommodating location information indicating the appropriate return location. The appropriate return location herein means the accommodating location where the battery 200 to be returned to the station 300 should be accommodated, among a plurality of accommodating locations in the battery-accommodating section 301 of the station 300. The management device 400 further includes a good return reward section 414 to judge whether the battery 200 has been returned to the appropriate return location based on the accommodating location information received from the location output section 412 and the information of the location where the battery 200 returned to the station 300 is accommodated, and a good usage reward section 416 to judge whether the deterioration degree received from the deterioration degree calculating section 411 meets the good usage condition.

Upon receiving the deterioration class of the battery 200 from the deterioration degree calculating section 411, the location output section 412 refers to the accommodating location condition stored in the condition storage section 425 to judge the accommodating location of the battery 200 based on the deterioration class and output it to the good return reward section 414.

Upon receiving the accommodating location information from the location output section 412 and receiving the information of the location where the returned battery 200 is accommodated from the station 300, the good return reward section 414 judges whether the location where the battery 200 is accommodated is the appropriate return location indicated in the accommodating location information. When judging that the battery 200 has been returned to the appropriate return location, the good return reward section 414 refers to the reward information storage section 437 and outputs the reward information to the station 300. When judging that the battery has not been returned to the appropriate return location, the good return reward section does not output the reward information.

Upon receiving the deterioration degree from the deterioration degree calculating section 411, the good usage reward section 416 refers to the good usage condition stored in the condition storage section 425 and judges whether the deterioration degree meets the good usage condition. When judging that the deterioration degree meets the good usage condition, the good usage reward section 416 refers to the reward information storage section 437 and outputs the reward information to the station 300. When judging that the deterioration degree does not meet the good usage condition, the good usage reward section does not output the reward information.

The management device 400 further includes the lending processing section 407 to perform the lending process on a particular battery 200 stocked in the station 300. The lending processing section 407 is managed by the management section 419, and judges whether the battery 200 stocked in the station 300 can be lent based on the related information stored in the related information storage section 219 and the related information of the battery 200 used in the vehicle 100, which is read by the reading section 401. When judging that the battery 200 can be lend, the lending processing section 407 outputs, to the station 300, the instruction to lend the battery 200.

It is noted that when judging that the battery 200 stocked in the station 300 can be lent, the lending processing section 407 may output the result to the writing section 417 and the writing section 417 outputs, to the station 300, the instruction to lend the battery 200, in place of the lending processing section 407. It is noted that when the management device 400 does not communicate with the server 500 and does not include the communication section 403 and the management section 419, the lending processing section 407 may judge whether the battery 200 stocked in the station 300 can be lent based on the related information of the battery 200 used in the vehicle 100, which is read by the reading section 401. In this case, the lending processing section 407 may also judge whether the battery 200 can be lent based on each pieces of information stored in the storage section 420.

When the vehicle ID read by the reading section 401 matches the vehicle ID included in the vehicle ID list stored in the ID list storage section 429, the lending processing section 407 may judge that the battery 200 stocked in the station 300 can be lent. Similarly, when the user ID read by the reading section 401 matches the user ID included in the user ID list stored in the ID list storage section 429, the lending processing section 407 may judge that the battery 200 can be lent. Similarly, when the battery ID read by the reading section 401 matches battery ID included in the battery ID list stored in the ID list storage section 429, the lending processing section 407 may judge that the battery 200 can be lent.

In addition, when the distance between the location of the home base indicated by the home base location information read by the reading section 401 and a predetermined address stored in the address distance storage section 433 is within a predetermined distance stored in the address distance storage section 433, the lending processing section 407 may judge that the stock battery 200 can be lent.

In addition, when the distance between the user address indicated by the user address information read by the reading section 401 and a predetermined address stored in the address distance storage section 433 is equal to or less than a predetermined distance stored in the address distance storage section 433, the lending processing section 407 may judge that the stock battery 200 can be lent.

In addition, when any of the location of the home base and the history of the path indicated by any of the home base location information and the path history information read by the reading section 401 is within a predetermined area stored in the area information storage section 435, the lending processing section 407 may judge that the stocked battery 200 can be lent.

When the user address indicated by the user address information read by the reading section 401 is within a predetermined area stored in the area information storage section 435, the lending processing section 407 may judge that the stocked battery 200 can be lent.

It is noted that the above-mentioned extracting and presenting the identifying information by the presenting section 405 may include outputting, to the station 300, the instruction to enable the battery 200 stocked in the station 300 to be provided to the user 60 based on the extracted identifying information. In other word, it may include outputting, to the battery-accommodating section 301, the instruction to enable, among a plurality of batteries 200 which is accommodated in the battery-accommodating section 301 of the station 300 and which is prohibited from being taken out from the outside, one or more batteries 200 identified based on the extracted identifying information to be taken out from the outside. In this case, the presenting section 405 and the lending processing section 407 may be one component as a whole.

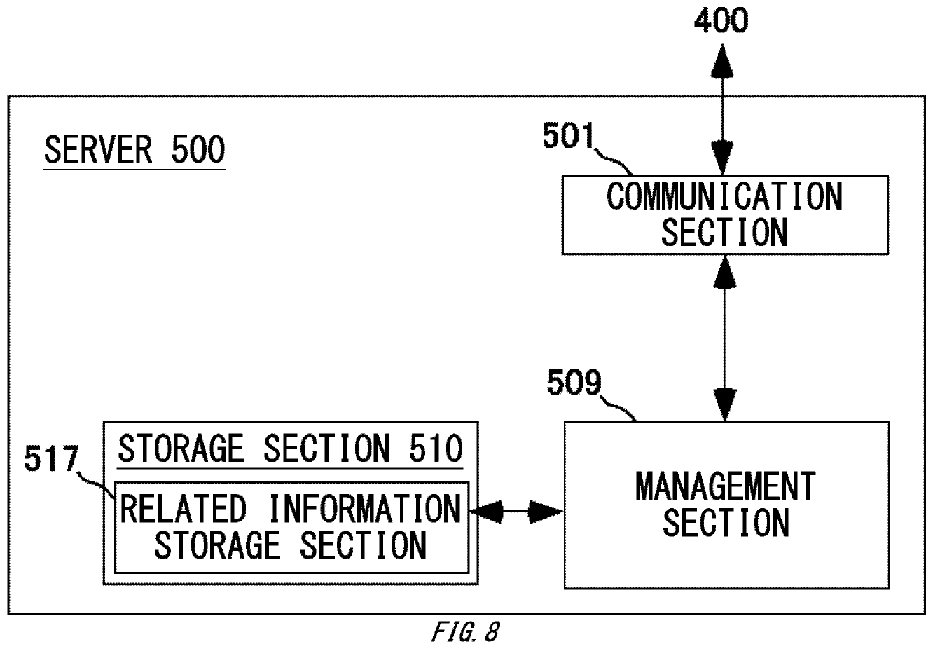

FIG. 8 is a block diagram of the server 500. The server 500 includes a communication section 501 to communicate with the management device 400 via the communication network 40, a storage section 510 including related information storage section 517 to store the related information, and a management section 509 to manage the related information of the vehicle 100 and the user 60 for which the battery 200 can be lent.

The management section 509 transmits, to the management device 400, the related information of the vehicle 100 and the user 60 for which the battery 200 can be lent, during communication with the management device 400. More specifically, the management section 509 centrally manages the related information collected from the plurality of management devices 400 and provides a part or all of the centrally managed related information to each of the management device 400 according to the request from each of the management device 400. More specifically, upon newly receiving related information from the communication section 501, the management section 509 stores and manages it in the related information storage section 517, and, in response to the request to transmit the related information from the management device 400 via the communication section 501, refers to the related information storage section 517 and transmits the related information to the management device 400. It is noted that the management section 509 may periodically or non-periodically transmit the related information to the management device 400 during communication with the management device 400 regardless of the request from the management device 400.

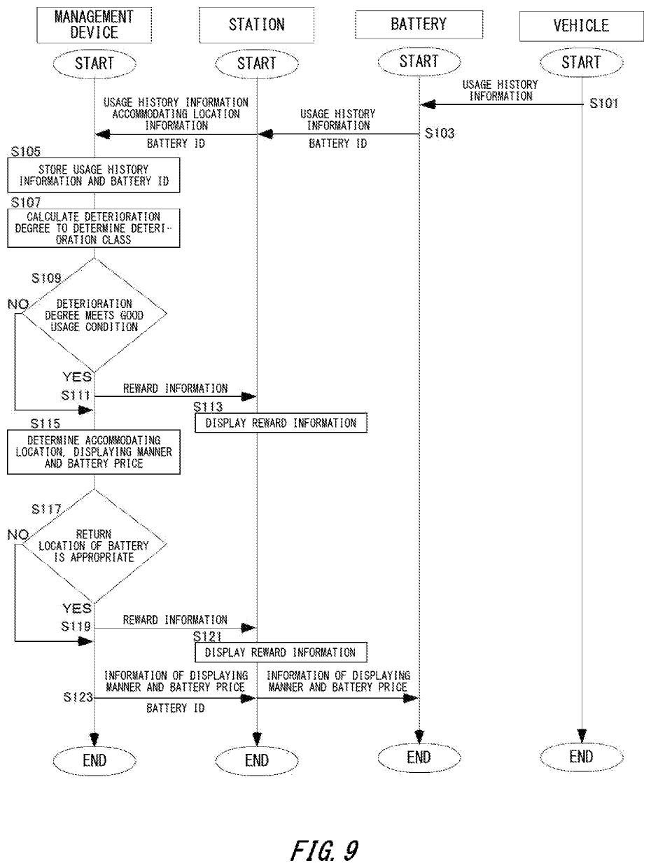

FIG. 9 is a flow diagram of the operation of the first embodiment. In the operation in FIG. 9, the management device 400 calculates the deterioration degree of the battery 200.

While the battery 200 is mounted to the vehicle 100 of the user 60, the usage history information is written from the vehicle 100 to the battery 200 (S101). When the battery 200 is returned to the station 300, the management device 400 reads the usage history information and battery ID written in the battery 200 via the station 300, and obtains the information of the location where the battery 200 is accommodated from the station 300 (S103).

The management device 400 stores the read usage history information and the battery ID (step S105). The management device 400 extracts the accumulated usage history information associated with the read battery ID, calculates the deterioration degree of the battery 200 based on the extracted accumulated usage history information, and determines the deterioration class (S107).

The management device 400 judges whether the calculated deterioration degree meets the good usage condition (S109). When the condition is met (S109: YES), the management device outputs the reward information to the station 300 (S111), and the station 300 displays the reward information (S113). When the calculated deterioration degree does not meet the good usage condition (S109: NO), the management device 400 does not output the reward information to the station 300.

The management device 400 determines the appropriate accommodating location of the battery 200, the display manner of the deterioration class, and the battery price (S115) based on the determined deterioration class. The management device 400 judges whether the actual accommodating location of the returned battery 200 is the appropriate accommodating location of the battery 200 determined based on the deterioration class (S117). If the battery 200 has been returned to the appropriate accommodating location (S117; YES), the management device outputs the reward information to the station 300 (S119), and the station 300 displays the reward information (S121). If the calculated deterioration degree does not meet the good usage condition (S117: NO), the management device 400 does not output the reward information to the station 300.

The management device 400 outputs, to the station 300, the information indicating the display manner of the deterioration class in the battery 200 and the battery price which are determined based on the deterioration class, along with the battery ID, and causes the information to be written to the battery 200 (S123), and the flow ends. It is noted that the station 300 may display the battery price indicated by the information according to the instruction from the management device 400.

According to the above-mentioned operation, because the management device 400 accumulates and stores the usage history information, the previous usage history information of the battery 200 can be used even when the battery 200 is being used. For example, the information can be used to predict the excess and deficiency of the battery 200 and plan the addition of the new battery 200, the collection of the old battery 200, and the like. In addition, if the management device 400 accumulates the usage history information in association with the user ID, the usage history information can be accumulated per user for the user 60 who used a plurality of batteries 200.

Furthermore, because the user 60 is given a reward in a case where the deterioration degree of the returned battery 200 meets the good usage condition, the user 60 can be encouraged for a good use of the battery 200. Furthermore, because the user 60 is also given a reward in a case where the battery 200 is returned to the return location specified by the station 300, the user 60 can be encouraged to return at the specified return location, and the battery 200 can be managed well.

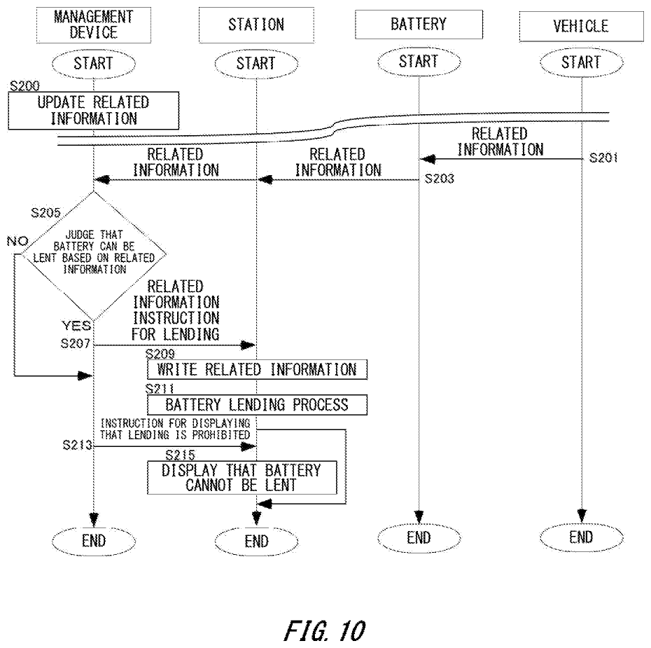

FIG. 10 is a flow diagram of another operation of the first embodiment. In the operation of FIG. 10, the management device 400 performs the lending process and the information succeeding process of the battery 200.

The management device 400 obtains the related information periodically managed by the server 500 in communication with the server 500, and updates the related information managed by the management device 400 (S200). On the other hand, the vehicle 100 writes the related information to the battery 200 while the battery is mounted do the vehicle 100 of the user 60 (S201). When the battery 200 is returned to the station 300, the management device 400 reads the related information written to the battery 200, via the station 300 (S203).

The management device 400 judges whether the battery 200 stocked in the station 300 can be lent based on the read related information (S205), and, if the battery can be lent (S205: YES), outputs the related information to the station 300 along with the lending instruction (S207).

The station 300 writes the related information to the stocked battery 200 (S209) and performs the lending process on the battery 200 (S211), and the flow ends.

On the other hand, according to the related information read by the management device 400, if the user 60 who returned the battery 200 to the station 300 or the vehicle 100 of the user 60 is not the subject to which the battery 200 can be lent (S205: NO), the management device 400 outputs, to the station 300, the instruction to display that the battery 200 stocked in the station 300 cannot be lent (S213).

The station 300 displays, on the display section 307, a message that the stocked battery 200 cannot be lent, according to the instruction from the management device 400, and the flow ends.

According to the above-mentioned operation, because whether the battery 200 can be lent is judged based on the related information read by the management device 400 from the battery 200, the labor such as presenting a member card can be saved, improving the convenience for the user 60. Furthermore, because the management device 400 updates the related information in communication with the server 500, it can more appropriately judge whether the battery 200 can be lent even if it cannot communicate with the server 500 or the server 500 has a fault, that is, the server is down.

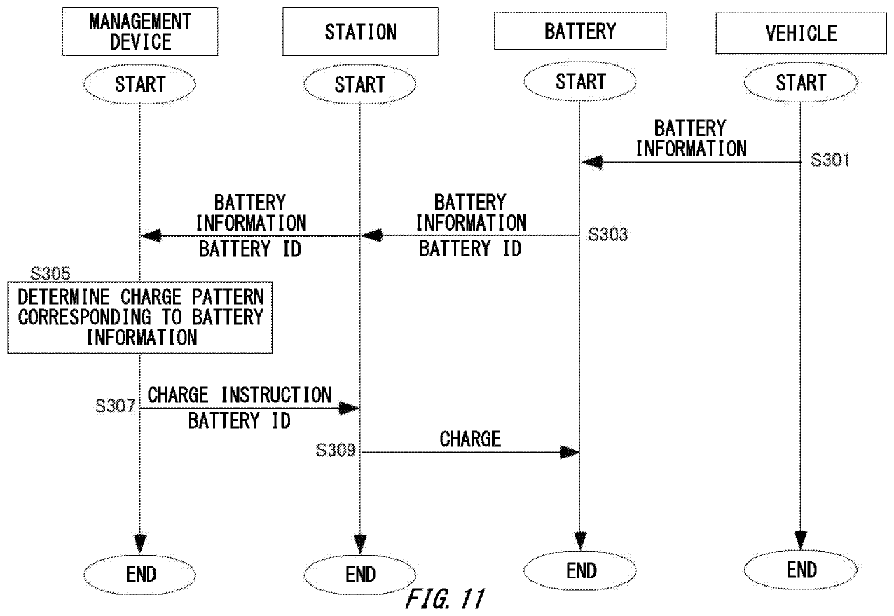

FIG. 11 is a flow diagram of yet another operation of the first embodiment. In the operation of the FIG. 11, the management device 400 determines the charge pattern of the battery 200.

When the flow shown in FIG. 11 starts, the vehicle 100 writes the battery information to the battery 200 mounted to the vehicle 100 of the user 60 (S301). When the battery 200 is returned to the station 300, the management device 400 reads the battery information written in the battery 200 along with the battery ID via the station 300 (S303).

The management device 400 determines the charge pattern corresponding to the read battery information among a plurality of stored charge patterns (S305), and outputs, to the station 300, the instruction to charge the battery 200 returned according to the determined charge pattern, along with the battery ID. The station 300 charges the battery 200 corresponding to the input battery ID according to the instruction to charge from the management device 400 (S309), and the flow ends.

According to the above-mentioned operation, because the charge pattern is stored in the management device 400 and the charge pattern is determined based on the related information read by the management device 400 from the battery 200, the charging suited to the battery 200 can be performed regardless of the state of the communication with the vehicle 100 and the location of the vehicle 100.

The steps of each operation in FIG. 9 to FIG. 11 may be performed in parallel to a step of another operation, or may be performed in a different order. In addition, each operation in FIG. 9 to FIG. 11 is performed repeatedly when each device such as the management device 400 is operable.

In the above-mentioned embodiment, the SOC calculating section 105 updates the SOC-OCV curve read from the battery 200, and calculates the current SOC of the battery 200 based on the updated SOC-OCV curve and the current voltage of the battery 200 input from the charge/discharge amount measuring section 103. Alternatively, the SOC calculating section 105 may also read the nominal capacitance of the battery 200 measured under a certain condition from the battery 200, measures the current discharge capacity of the battery 200 under the same certain condition, and calculate the SOC as a ratio of the current discharge capacity to the nominal capacitance. Alternatively, the SOC calculating section 105 may roughly measure the SOC by reading, from the battery 200, the SOC-OCV curve of the battery 200 premeasured under a particular condition, measuring the current voltage of the battery 200 under the same particular condition, and comparing it with the SOC-OCV curve.

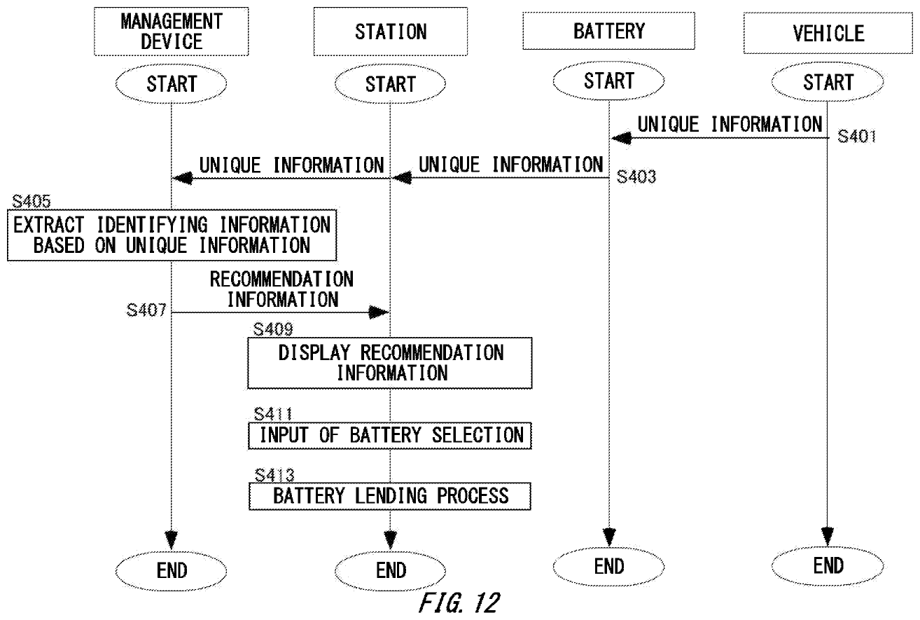

FIG. 12 is a flow diagram according to the second embodiment. The operation in FIG. 12 is another example of the operation in FIG. 10. The management system 20 in the second embodiment includes the same components as the management system 20 in the first embodiment, and the overlapped explanation is omitted.

The vehicle 100 writes unique information to the battery 200 while the battery is mounted to the vehicle 100 of the user 60 (S401). When the battery 200 is returned to the station 300, the management device 400 reads the unique information written in the battery 200, via the station 300 (S403).

The management device 400 extracts the identifying information to identify the battery 200 stocked in the station 300 based on the read unique information (S405), and outputs, to the station 300, the recommendation information to recommend the battery 200 suited to the user 60 (S407).

The station 300 displays the recommendation information received from the management device 400 on the display section 307 (S109), accepts the input for selecting a battery from the user 60 via the input section 309 (S411), and performs the lending process of the battery according to the input (S413), and the flow ends. The flow is performed repeatedly while each device such as the management device 400 is operable.

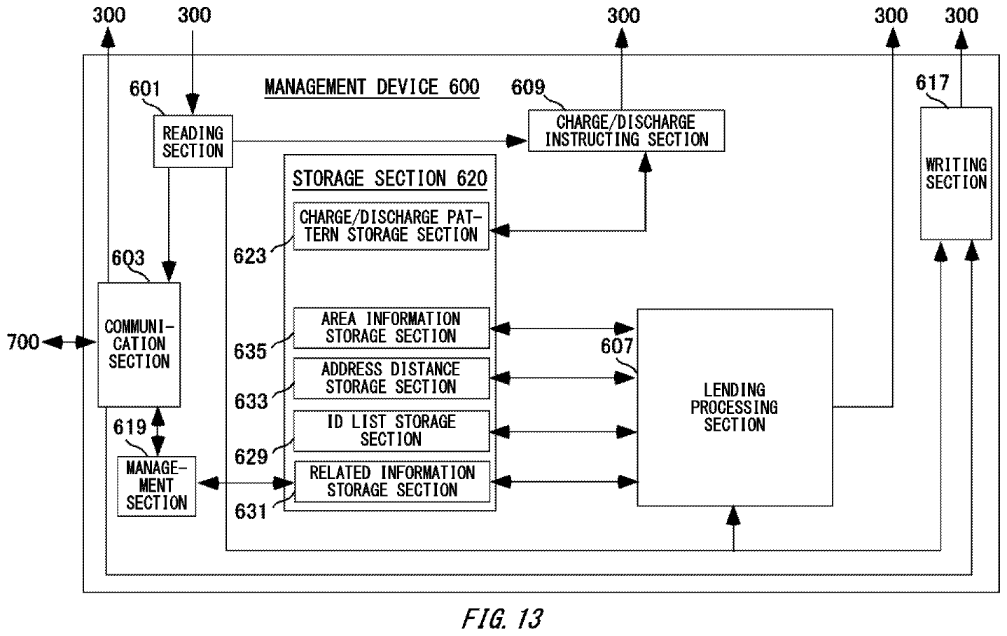

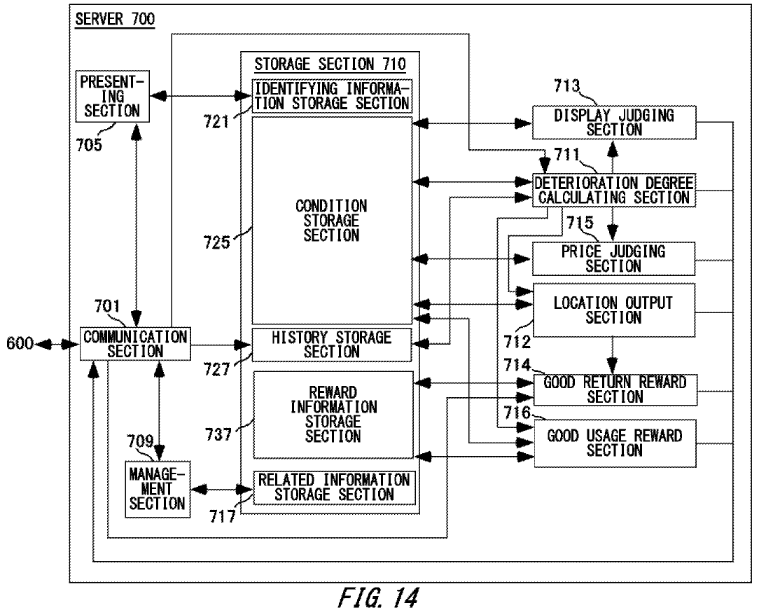

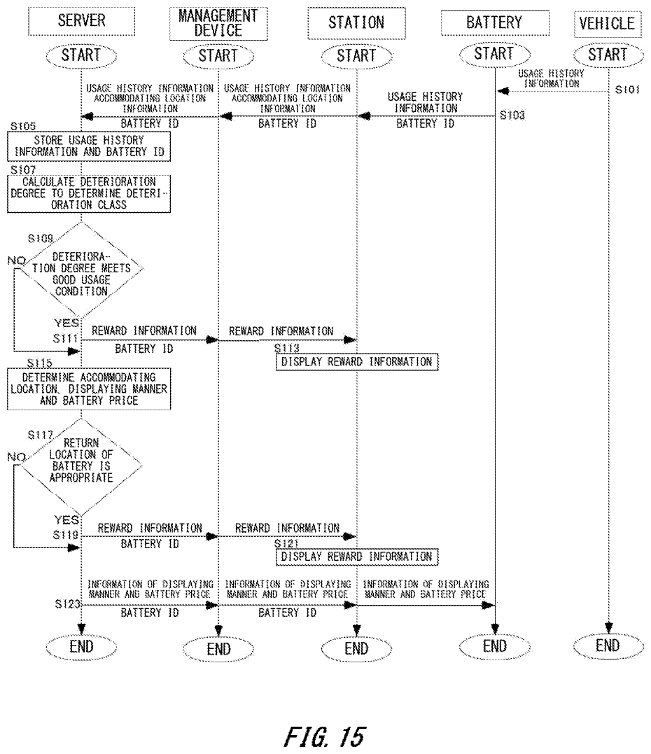

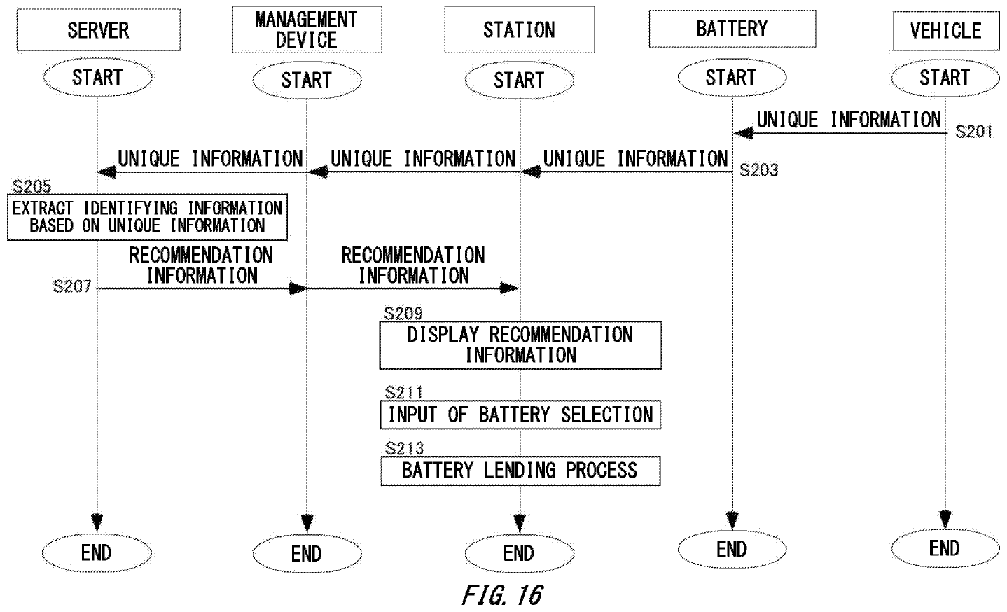

FIG. 13 is a block diagram of the management device 600 according to the third embodiment. FIG. 14 is a block diagram of the server 700 according to the third embodiment. FIG. 15 and FIG. 16 are flow diagrams according to the third embodiment.

Each component and function of the management device 600 and the server 700 according to the third embodiment is different from a part of the components and function of the management device 400 and the server 500 according to the first embodiment. Specifically, the server 700 according to the third embodiment has a part of the components and the function of the management device 400 according to the first embodiment, while the management device 600 according to the third embodiment does not have the part of the components and the function. It is noted that the management system 20 in the third embodiment includes the same components as the management system 20 in the first embodiment, and the overlapped explanation is omitted. In addition, in FIG. 13 to FIG. 16, the same or similar reference numbers are attached to the same components as those in FIG. 1 to FIG. 11. The overlapped explanation is omitted. Only difference is explained.

The management device 600 shown in FIG. 13 includes a reading section 601, a communication section 603, a lending processing section 607, a charge/discharge instructing section 609, a writing section 617, a management section 619, and a storage section 620. The storage section 620 includes a charge/discharge pattern storage section 623, an ID list storage section 629, a related information storage section 631, an address distance storage section 633, and an area information storage section 635.

The reading section 601 reads a battery ID, usage history information, unique information, or the like from the battery 200 returned to the station 300, and transmits them to the server 700 via the communication section 603. In addition, upon receiving from the station 300 the information of the location where the battery 200 returned to the station 300 is accommodated, the reading section 601 transmits it to the server 700 via the communication section 603.

Upon receiving reward information and a battery ID from the server 700, the communication section 603 outputs the information to the station 300, and outputs, to the station 300, the instruction to display the reward information to the user 60 who has returned the battery 200 corresponding to the battery ID. In addition, upon receiving, from the server 700, the information related to the battery 200 returned to the station 300, such as a deterioration degree, a deterioration class, a display manner, a battery price, or the like, the communication section 603 outputs it to the writing section 617.

Upon obtaining the above-mentioned information from the server 700 via the communication section 603, the writing section 617 writes the above-mentioned information to the battery 200 returned to the station 300.

The server 700 indicated in FIG. 14 includes a presenting section 705, a deterioration degree calculating section 711, a display judging section 713, a price judging section 715, a location output section 712, a good return reward section 714, and a good usage reward section 716 in addition to a communication section 701, a management section 709, and a storage section 710. The storage section 710 also includes a identifying information storage section 721, a condition storage section 725, a history storage section 727, and a reward information storage section 737, in addition to a related information storage section 717. The communication section 701 is one example of the receiving section.

Upon receiving usage history information and a battery ID from the management device 600, the communication section 701 outputs the battery ID to the deterioration degree calculating section 711, and stores the usage history information in association with the battery ID in the history storage section 727. In addition, upon receiving the unique information and the battery ID from the management device 600, the communication section 701 outputs them to the presenting section 705. In addition, upon receiving, from the management device 600, the information of the location where the battery 200 returned to the station 300 is accommodated, the communication section 701 outputs it to the good return reward section 714.

Upon receiving the unique information and the battery ID from the communication section 701, the presenting section 705 refers to the identifying information storage section 721 and extracts the identifying information based on the unique information. The presenting section 705 transmits the extracted identifying information along with the battery ID to the management device 400 via the communication section 701.

Upon receiving the battery ID from the communication section 701, the deterioration degree calculating section 711 extracts the accumulated usage history information stored in the history storage section 727 by using the battery ID, and calculates the deterioration degree based on the extracted accumulated usage history information.

Each of the deterioration degree calculating section 711, the display judging section 713, the price judging section 715, the good return reward section 714, and the good usage reward section 716 transmits the output information to the management device 400 via the communication section 701.

FIG. 15 is a flow diagram of the operation of the third embodiment. In the operation in FIG. 15, the server 700 calculates the deterioration degree or the like of the battery 200.

While the battery 200 is mounted to the vehicle 100 of the user 60, the usage history information is written from the vehicle 100 to the battery 200 (S101). When the battery 200 is returned to the station 300, the management device 600 reads the usage history information and battery ID written in the battery 200 via the station 300, obtains the information of the location where the battery 200 is accommodated from the station 300, and transmits the information to the server 700 (S103).

The server 700 stores the read usage history information and battery ID (S105). The server 700 extracts the accumulated usage history information associated with the read battery ID, calculates the deterioration degree of the battery 200 based on the extracted accumulated usage history information, and determines the deterioration class (S107).

The server 700 judges whether the calculated deterioration degree meets the good usage condition (S109). If the good usage condition is met (S109: YES), the reward information and the battery ID are transmitted to the management device 600, the management device 600 outputs the reward information to the station 300 (S111), and the station 300 displays the reward information (S113). If the calculated deterioration degree does not meet the good usage condition (S109: NO), the server 700 does not transmit the reward information to the management device 600.

The server 700 determines the appropriate accommodating location for the battery 200, the display manner of the deterioration class, and the battery price based on the determined deterioration class (S115). The server 700 judges whether the actual accommodating location of the returned battery 200 is the appropriate accommodating location of the battery 200 determined based on the deterioration class (S117). If the battery 200 has been returned to the appropriate accommodating location (S117: YES), the battery ID is transmitted to the management device 600, the management device 600 outputs the reward information to the station 300 (S119), and the station 300 displays the reward information (S121). If the calculated deterioration degree does not meet the good usage condition (S117: NO), the server 700 does not transmit the reward information to the management device 600.

The server 700 transmits, to the management device 600, the information indicating the display manner of the deterioration class in the battery 200 and the battery price which are determined based on the deterioration class, along with the battery ID. The management device 600 outputs the information to the station 300 and causes the information to be written to the battery 200 (S123) and the flow ends. It is noted that the station 300 may, according to the instruction from the server 700, display the battery price indicated by the information.

FIG. 16 is a flow diagram of another operation of the third embodiment. In the operation of FIG. 16, the server 700 performs the lending process and the information succeeding process of the battery 200.

While the battery 200 is mounted to the vehicle 100 of the user 60, the unique information is written from the vehicle 100 to the battery 200 (S201). When the battery 200 is returned to the station 300, the management device 600 reads, via the station 300, the unique information written in the battery 200 and transmits it to the server 700 (S203).

The server 700 extracts the identifying information to identify the battery 200 stocked in the station 300 based on the unique information (S205) and transmits the recommendation information to recommend the battery 200 suited to the user 60 to the management device 600, and the management device 600 outputs the recommendation information to the station 300 (S207).

The station 300 displays the recommendation information received from the server 700 on the display section 307 (S109), accepts the input for selecting a battery from the user 60 via the input section 309 (S211), and performs the battery lending process according to the input (S213), and the flow ends.

According to the above-mentioned operation, because the server 700 performs the information succeeding process of the battery 200, among the information of a plurality of batteries 200 returned to the different stations 300, the information of the same user 60 or the same vehicle 100 can also be grouped together and succeeded to the next battery 200.

The steps of each operation in FIG. 15 and FIG. 16 may be performed in parallel to a step of another operation, or may be performed in a different order. In addition, each operation in FIG. 15 and FIG. 16 is performed repeatedly while each device such as the management device 600 is operable.

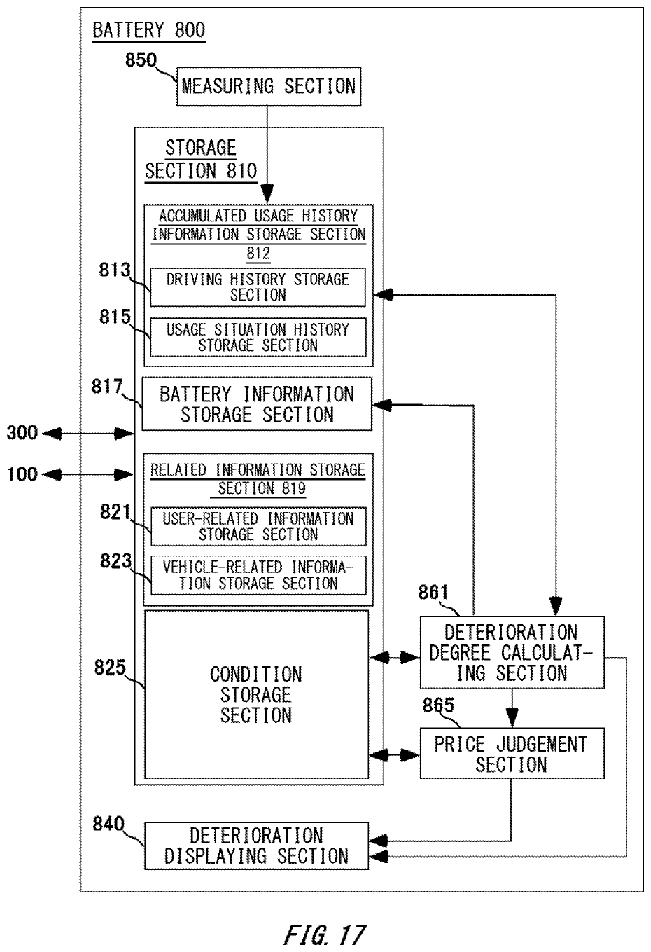

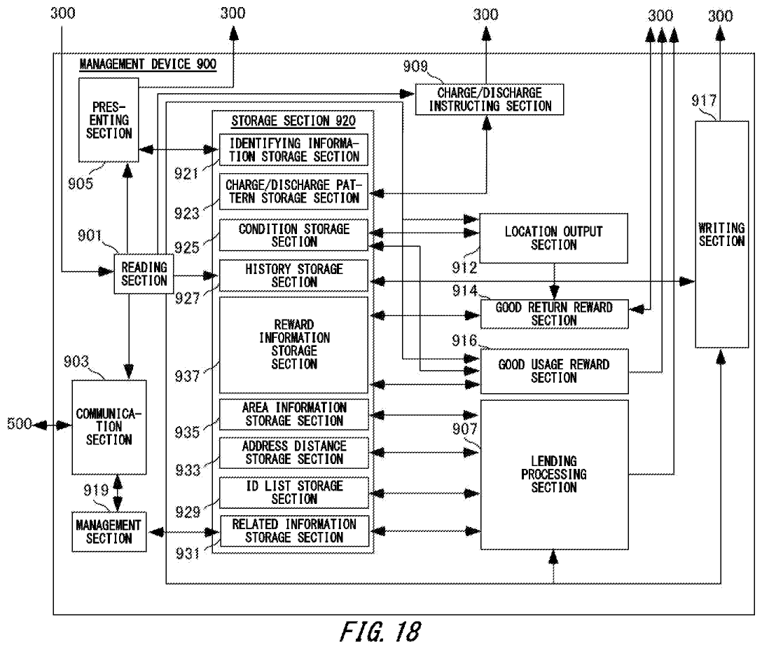

FIG. 17 is a block diagram of the battery 800 according to the fourth embodiment. FIG. 18 is a block diagram of the management device 900 according to the fourth embodiment.

Each component and function of the battery 800 and the management device 900 according to the fourth embodiment is different from a part of the components and function of the battery 200 and the management device 400 according to the first embodiment. In FIG. 17 to FIG. 19, the same or corresponding reference numbers are attached to the same components as that of FIGS. 1 to 11, and the overlapped explanation is omitted.

The battery 800 shown in FIG. 17 includes a storage section 810, a deterioration displaying section 840, a measuring section 850, a deterioration degree calculating section 861, and a price judging section 865. The storage section 810 includes an accumulated usage history information storage section 812, a battery information storage section 817, a related information storage section 819, and a condition storage section 825.

The measuring section 850 measures the charge/discharge amount of the battery 800 and stores the accumulated usage history information storage section 812. More specifically, the measuring section 850 measures the current flowing into/out of the battery 800 and the voltage of the battery 800, and calculates the power amount by integrating the current and voltage.

The accumulated usage history information storage section 812 stores the accumulated usage history information which is the information which accumulates the usage history information. The usage history information includes the history information of the charge/discharge amount of the battery 800 measured by the measuring section 850. The usage history information may be stored in association with the vehicle ID of the vehicle 100 to which the battery 800 is mounted. It is noted that although the accumulated usage history information preferably includes the usage history information of all drive cycles during the period from the moment when the battery 800 starts to be used as a new product to the current moment, the usage history information of some of the drive cycles may be lacked. The accumulated usage history information storage section 812 includes a driving history storage section 813 and a usage situation history storage section 815.

The condition storage section 825 stores the deterioration class condition to judge the deterioration class based on the deterioration degree of the battery 800 and the price condition to judge the price of the battery 800 based on the deterioration class of the battery 800. The related information storage section 819 includes a user-related information storage section 821 and a vehicle-related information storage section 823.

The deterioration degree calculating section 861 periodically or non-periodically calculates the deterioration degree based on the accumulated usage history information stored in the accumulated usage history information storage section 812, refers to the condition storage section 825, and determines the deterioration class based on the calculated deterioration degree. The deterioration degree calculating section 861 outputs the information of the deterioration class to the price judging section 865 and also outputs it to the deterioration displaying section 840 to display the deterioration class visibly to the outside. Furthermore, the deterioration degree calculating section 861 stores the information of the deterioration degree and deterioration class in the battery information storage section 817.

Upon receiving the information of the deterioration class from the deterioration degree calculating section 861, the price judging section 865 refers to the condition storage section 825, determines the battery price based on the deterioration class, outputs it to the deterioration displaying section 840, and displays the battery price visibly to the outside. It is noted that the condition storage section 825 may store the price condition to judge the battery price based on the deterioration degree, and the price judging section 865, upon receiving the information of the deterioration degree from the deterioration degree calculating section 861, may refer to the condition storage section 825 and determine the battery price based on the deterioration degree. It is noted that the deterioration degree calculating section 861 and the price judging section 865 are one example of the calculating section.

The management device 900 shown in FIG. 18 includes a reading section 901, a communication section 903, a presenting section 905, a lending processing section 907, a charge/discharge instructing section 909, a location output section 912, a good return reward section 914, a good usage reward section 916, a writing section 917, a management section 919, a storage section 920. The storage section 920 includes a identifying information storage section 921, a charge/discharge pattern storage section 923, a condition storage section 925, a history storage section 927, an ID list storage section 929, a related information storage section 931, an address distance storage section 933, an area information storage section 935, and a reward information storage section 937.

The reading section 901 reads the battery ID, the usage history information, the deterioration degree information, the deterioration class information, or the like from the battery 800 returned to the station 300, stores them in the history storage section 927, and outputs them to the writing section 917. In addition, the reading section 901 outputs he read deterioration class information to the location output section 912, and outputs the deterioration degree information to the good usage reward section 916.

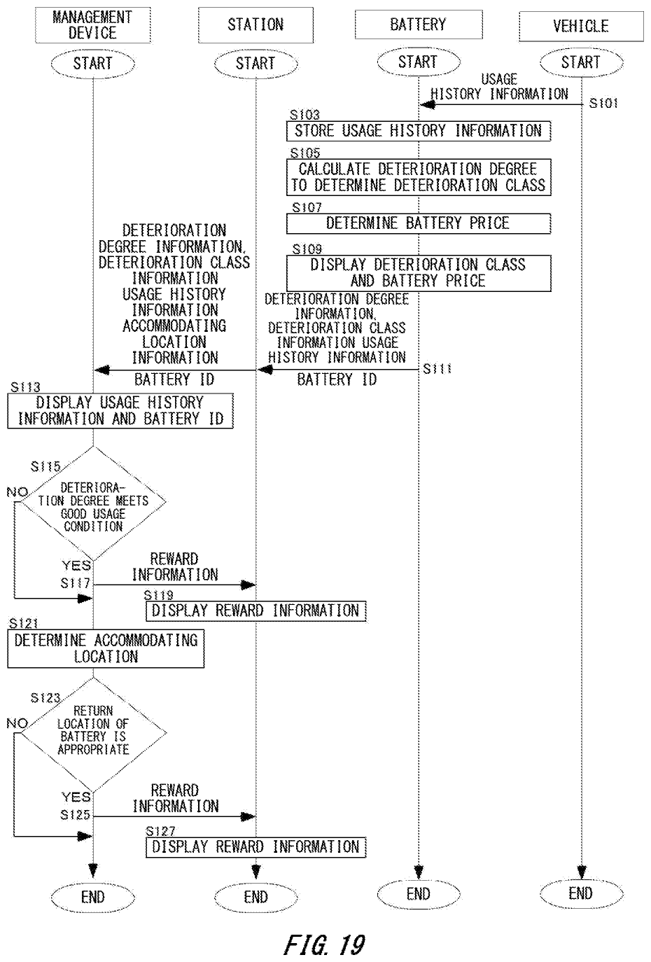

FIG. 19 is a flow diagram of the operation of the fourth embodiment. In the operation of the FIG. 19, the battery 800 calculates the own deterioration degree.

When the usage history information is written to the battery 800 by the vehicle 100 of the user 60 with the battery 800 mounted to the vehicle 100 (S101), the usage history information is stored (S103). The battery 800 calculates the deterioration degree based on the stored accumulated usage history information and determines the deterioration class based on the deterioration degree (S105).

The battery 800 determines the battery price based on the determined deterioration class (S107) and displays the determined deterioration class and battery price visibly to the outside (S109).

When the battery 800 is returned to the station 300, the management device 900 reads the usage history information, deterioration degree information, deterioration class information, or the like written in the battery 800 along with the battery ID via the station 300, and obtains the information of the location where the battery 800 is accommodated from the station 300 (S111).

The management device 900 stores the read usage history information and battery ID (S113). The management device 900 judges whether the deterioration degree indicated by the read deterioration degree information meets the good usage condition (S115).

When the condition is met (S115: YES), the reward information is output to the station 300 (S117), and the station 300 displays the reward information (S119). If the calculated deterioration degree does not meet the good usage condition (S115: NO), the management device 900 does not output the reward information to the station 300.

The management device 900 determines the appropriate accommodating location of the battery 800 based on the deterioration class read from the battery 800 (S121). The management device 900 judges whether the actual accommodating location of the returned battery 800 is the appropriate accommodating location of the battery 800 determined based on the deterioration class (S123).

If the battery 800 has been returned to the appropriate accommodating location (S123: YES), the reward information is output to the station 300 (S125), the station 300 displays the reward information (S127) and the flow ends. If the calculated deterioration degree does not meet the good usage condition (S123: NO), the management device 900 does not output the reward information to the station 300 and the flow ends. The flow is performed repeatedly while each device such as the management device 900 is operable. It is noted that the station 300 may display the deterioration class and the battery price read from the battery 800.

According to the above-mentioned operation, because the deterioration degree, the deterioration class and the price are determined by the battery 200 itself, the user 60 can continuously learn the deterioration degree or the like while the battery 200 is used. Furthermore, because the deterioration degree or the like of the battery 200 has been updated to the latest state when the battery 200 is returned to the station 300, the station 300 does not have to determine the deterioration degree or the like again, facilitating the process at the time of return.

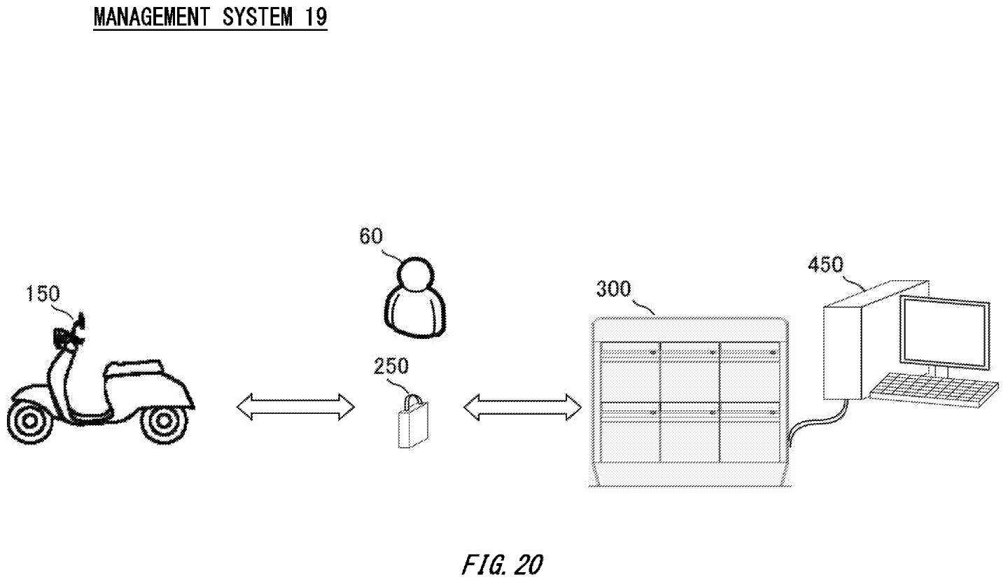

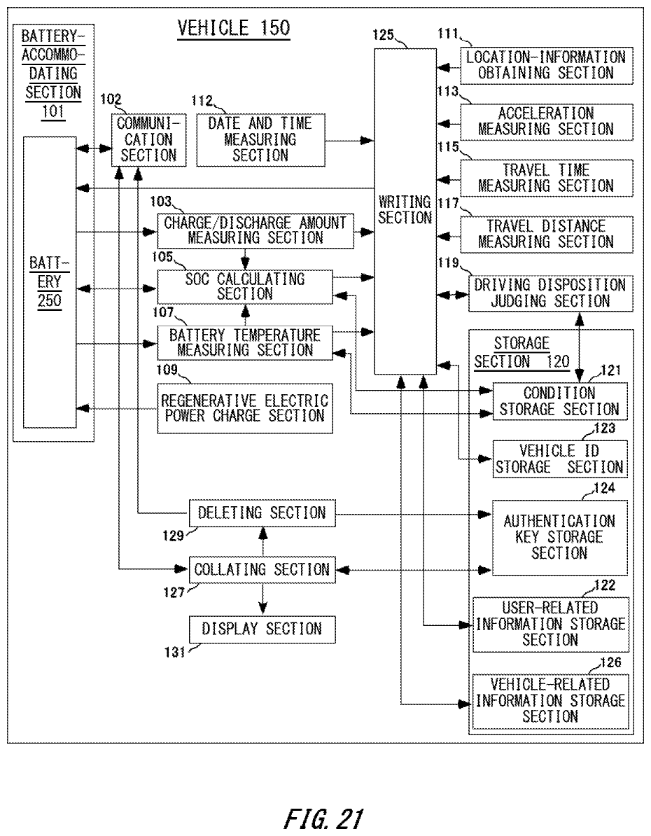

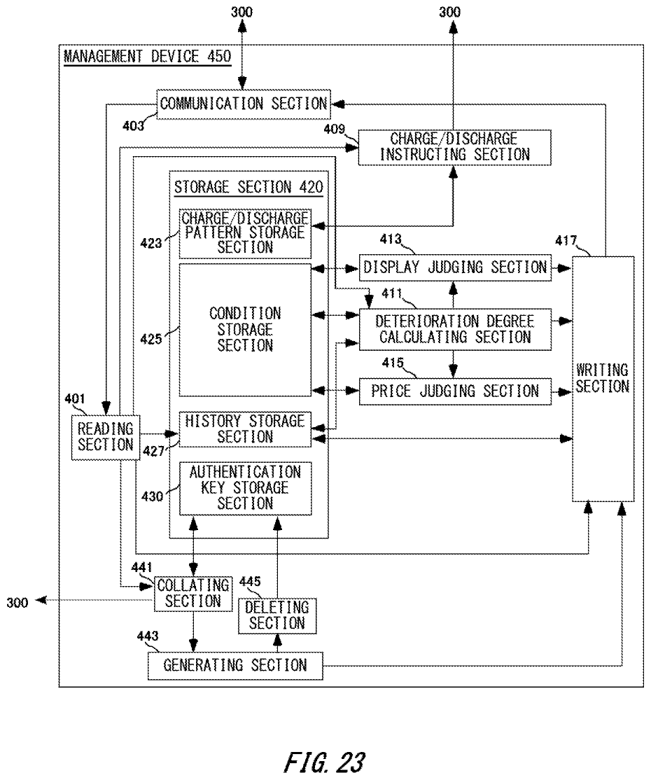

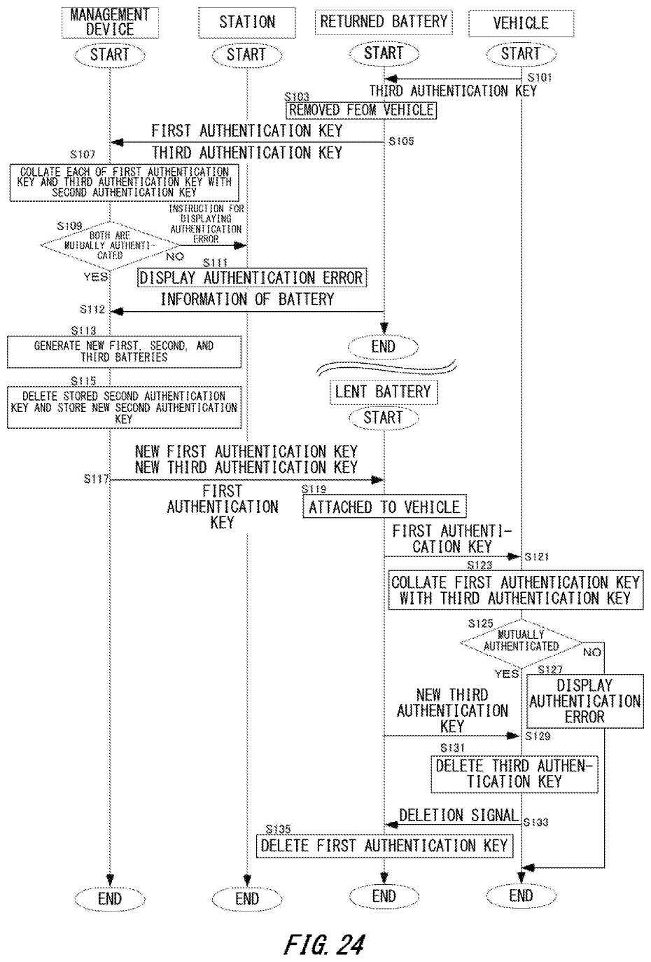

FIG. 20 is a schematic diagram of the management system 19 according to the fifth embodiment. In addition, FIG. 21 and FIG. 23 are block diagrams of each component according to the fifth embodiment. FIG. 24 is a flow diagram according to the fifth embodiment.

As shown in FIG. 20, the management system 19 according to the fifth embodiment does not include the server 500 unlike the management system 20 according to the first embodiment, and each component does not perform a communication via the communication network 40. Each component and function of the vehicle 150, the battery 250, and the management device 450 according to the fifth embodiment is partially different from the component and function of the vehicle 100, the battery 200, and the management device 400 according to the first embodiment. In FIG. 20 to FIG. 24, the same or corresponding reference numbers are attached to the same component as that of FIGS. 1 to 11, and the overlapped explanation is omitted.

If the authentication succeeds with the authentication key read from the battery 250 returned to the station 300, the management system 19 generates a new authentication key and writes it to the battery 250 to be lent to the vehicle 150 next time. With the updating of the authentication key, the user 60 will not have a complaint due to a counterfeit whose quality is not ensured being used.

FIG. 21 is a block diagram of the vehicle 150. The storage section 120 of the vehicle 150 includes an authentication key storage section 124. The vehicle 150 further includes a communication section 102 to communicate with the battery 250 accommodated in the battery-accommodating section 101, a collating section 127 to collate the authentication key, a deleting section 129 to transmit, to the battery 250, a deleting signal to delete an old authentication key via the communication section 102, and a display section 131 to display any message, for example, a message of an authentication error.

The authentication key storage section 124 stores the authentication key. The authentication key storage section 124 stores a third authentication key for the vehicle 150 which can be mutually authenticated with a first authentication key for the battery 250 written in the battery 250 and a second authentication key for the management device 450.

When the battery 250 is accommodated in the battery-accommodating section 101, the communication section 102 reads the first authentication key written in the battery 250 via wired communicate or wireless communicate and outputs it to the collating section 127.

Upon receiving the first authentication key from the communication section 102, the collating section 127 obtains the third authentication key stored in the authentication key storage section 124 and collates the first authentication key with the third authentication key. If the mutual authentication succeeds between the first authentication key and the third authentication key, the collating section 127 outputs the authentication information indicating the result to the deleting section 129. If the mutual authentication fails between the first authentication key and the third authentication key, the collating section 127 outputs, to the display section 131, the instruction to display the message of the authentication error and causes the message to be displayed.

Upon receiving authentication information from the collating section 127, the deleting section 129 causes the communication section 102 to read a new third authentication key written in the battery 250 accommodated in the battery-accommodating section 101 and store it in the authentication key storage section 124. The deleting section 129 further deletes an old third authentication key stored in the authentication key storage section 124. The deleting section 129 further deletes an old first authentication key written in the battery 250, via the communication section 102. It is noted that although a new first authentication key is also written in the battery 250, the deleting section 129 selectively prevents the new first authentication key from being deleted.

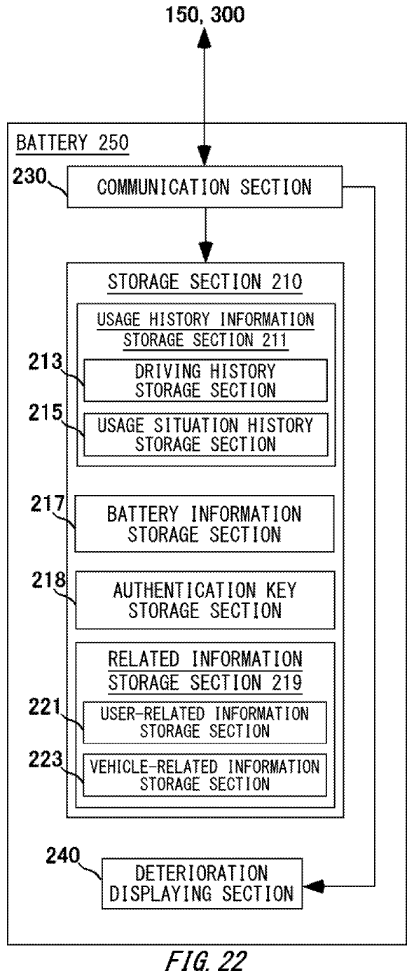

FIG. 22 is a block diagram of the battery 250. The storage section 210 of the battery 250 includes an authentication key storage section 218 to store the authentication key. The authentication key storage section 218 stores the first authentication key and the third authentication key. The battery 250 includes a communication section 230 to communicate with the station 300 and the vehicle 150.

Upon receiving the instruction to read and write the information stored in the storage section 210 from the management device 450 via the station 300, the communication section 230 performs reading and writing of the information according to the instruction and transmits the read information to the station 300. In addition, upon receiving a deleting signal from the vehicle 150, the communication section 230 deletes an old first authentication key stored in, for example, the authentication key storage section 218 according to the deleting signal. In addition, upon receiving the instruction to display the current deterioration state of the battery 250 from the station 300, the communication section 230 outputs it to the deterioration displaying section 240.

FIG. 23 is a block diagram of the management device 450. The storage section 420 of the management device 450 includes an authentication key storage section 430 to store the authentication key. The authentication key storage section 430 stores, for example, a second authentication key.

The management device 450 includes a collating section 441 to collate the authentication key, a generating section 443 to generate a new authentication key, and a deleting section 445 to delete an old authentication key stored in the authentication key storage section 430.

Upon receiving the first authentication key and the third authentication key from the reading section 401, the collating section 441 obtains the second authentication key stored in the authentication key storage section 430 and collates each of the first authentication key and the third authentication key with the second authentication key. If the mutual authentication succeeds between each of the first authentication key and the third authentication key and the second authentication key, the collating section 441 outputs authentication information indicating the result to the generating section 443. If the mutual authentication fails between at least any of the first authentication key and the third authentication key and the second authentication key, the collating section 441 outputs, to the display section 307 of the station 300, an instruction to display a message of the authentication error and causes the message to be displayed. The message may indicate the pair of the authentication key for which the mutual authentication failed.

Upon receiving the authentication information from the collating section 441, the generating section 443 generates three new authentication keys which can be mutually authenticated. Specifically, the generating section 443 generates a new second authentication key, a new first authentication key, and a new third authentication key. The generating section 443 outputs the new second authentication key to the deleting section 445, and outputs the new first authentication key and the new third authentication key to the writing section 417 along with the old first authentication key.

Upon receiving the new second authentication key from the generating section 443, the deleting section 445 stores the new second authentication key in the authentication key storage section 430, and deletes a second authentication key stored in advance in the authentication key storage section 430, that is, the old second authentication key. Storing the new second authentication key in the authentication key storage section 430 and deleting the old second authentication key stored in the authentication key storage section 430 may be performed in a predetermined order, or may be performed in any order.

As described above, an authentication key which exists before an authentication key is generated by the generating section 443 may be called an old authentication key, and the authentication key generated by the generating section 443 may be called a new authentication key.

Upon receiving the new first authentication key generated by the generating section 443 and the new third authentication key along with the old first authentication key, the writing section 417 outputs, to the station 300, the instruction to write to the battery 250 to be lent from the station 300 to the user 60 who returned the battery 250.

Only to clarify the explanation, the management device 450 in the present embodiment does not include the presenting section 405, the management section 419, the lending processing section 407, the location output section 412, the good return reward section 414, and the good usage reward section 416 of the management device 400 according to the first embodiment shown in FIG. 7, and also does not include the ID list storage section 429, the related information storage section 431, the address distance storage section 433, the area information storage section 435, and the reward information storage section 437 included in the storage section 420 of the management device 400. However, the management device 450 in the present embodiment may include a part or all of these components which are included in the management device 400 according to the first embodiment.

FIG. 24 is a flow diagram according to the fifth embodiment. The explanation of the flow in FIG. 24 starts when the particular user 60 returns the battery 250 used in the own vehicle 150 to the station 300.

While the battery 250 is mounted to the vehicle 150, the vehicle 150 writes the third authentication key to the battery 250 in advance (S101). When the vehicle 150 is removed from the battery 250 (S103) and returned to the station 300, the management device 450 reads the first authentication key and the third authentication key written in the battery 250, via the station 300 (S105).

The management device 450 collates each of the read first authentication key and third authentication key with the second authentication key retained in the management device 450 (S107).

If the mutual authentication fails between any of the first authentication key and the third authentication key, and the second authentication key (S109: NO), the instruction to display the authentication error is output to the station 300 (S111), and the flow ends. If the mutual authentication succeeds between both of the first authentication key and the third authentication key, and the second authentication key (S109: YES), the information of the battery 250 returned to the station 300 is read (S112). It is noted that if the mutual authentication fails, the station 300 cannot read the information of the battery 250.

The management device 450 generates a new first authentication key, a new second authentication key, and a new third authentication key (S113), deletes the old second authentication key stored in the management device 450, and stores the new second authentication key (S115).

The management device 450 outputs, to the station 300, the instruction to write the new first authentication key and the new third authentication key along with the old first authentication key to the battery 250 to be lent to the user 60 and perform the lending process (S117). In this case, even if another first authentication key and third authentication key are stored in advance in the battery 250 to be lent, they are updated to the above-mentioned first authentication key and the third authentication key. It is noted that the management device 450 preferably lends the battery 250 in which the charge has been completed.

When the user 60 mounts, to the vehicle 150, the battery 250 lent by the station 300 (S119), the vehicle 150 reads the old first authentication key from the battery 250 (S121), and collates the old first authentication key with the old third authentication key that the user has himself/herself (S123).

If the mutual authentication fails between the old first authentication key and the old third authentication key (S125: NO), the vehicle 150 displays a message of the authentication error (S127) and the flow ends. If the mutual authentication between the first authentication key and the third authentication key succeeds (S125: YES), the vehicle 150 reads a new third authentication key from the battery 250 and stores it (S129), and deletes the old third authentication key that the vehicle has himself/herself (S131). The vehicle 150 additionally transmits a deleting signal to the battery 250 (S133), causing the old first authentication key and the new third authentication key written in the battery 250 to be deleted (S135), and the flow end. The flow in FIG. 24 described above is performed repeatedly while each device such as management device 450 operates.

In the above-mentioned embodiment, in S125, the vehicle 150 may optionally perform writing process and reading process of the information on the battery 250 as long as the mutual authentication of the authentication key with the lent battery 250 succeeds.

According to the management system 19 in the present embodiment described above, even if a malicious third party illegally obtains a first authentication key from the battery 250 and writes it to a low price counterfeit whose quality is not ensured, the counterfeit cannot succeed in the authentication because the first authentication key has been updated to a new authentication key in a case where the genuine battery 250 in which the first authentication key is stored has been returned to the station 300. Therefore, the counterfeit cannot be applied to any of the management device 450 and the vehicle 150. This can prevent the user 60 from unintentionally borrowing a counterfeit from the station 300, and from having, for example, a complaint for a travel with low horsepower, high battery consumption, or the like as a result of borrowing a counterfeit assuming that it is the battery 250 of a genuine product.

In addition, according to the above-mentioned arrangement, because both of the management device 450 and the vehicle 150 does not perform any of the writing process and reading process of the information on the battery 250 if they fail the mutual authentication of the authentication key with the accommodate battery 250, the illegal leak of the information via the counterfeit can be prevented.

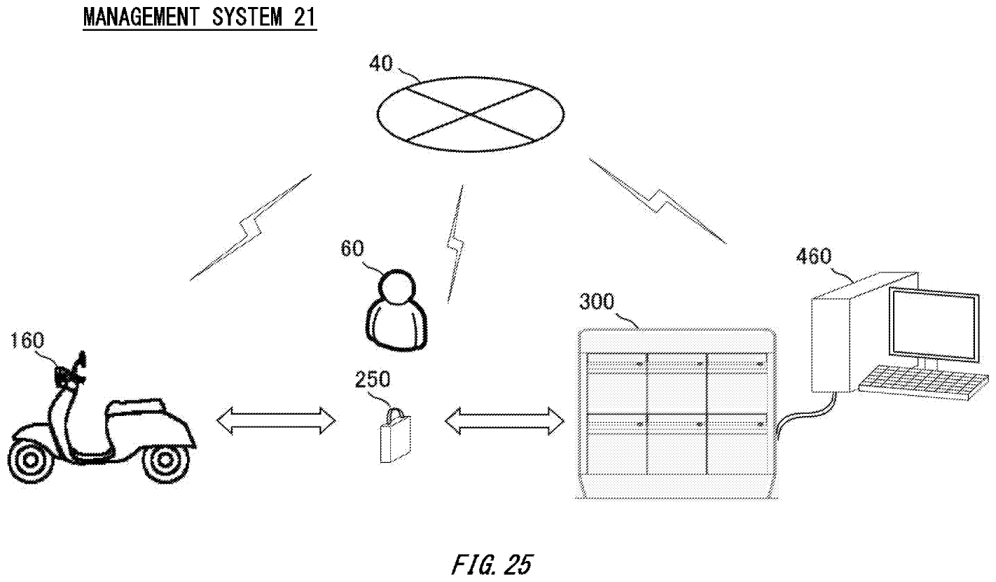

FIG. 25 is a schematic diagram of the management system 21 according to the sixth embodiment. In the management system 21, the same component as that of the management system 19 in the fifth embodiment is attached with the same number, and the explanation is omitted. As shown in FIG. 25, in the management system 21, the vehicle 160, the battery 250, and the management device 460 communicate with each other via the communication network 40.

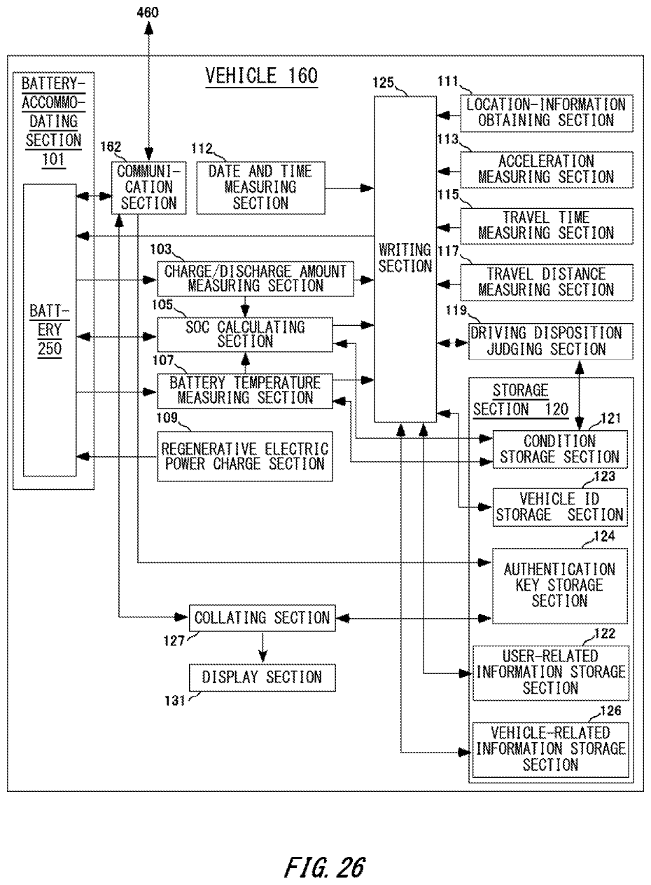

FIG. 26 is a block diagram of the vehicle 160. The difference is that the vehicle 160 does not have the deleting section 129, and the communication section 162 communicates with the management device 460. Besides, for the same component as that of the vehicle 150 in the fifth embodiment, the explanation is omitted.

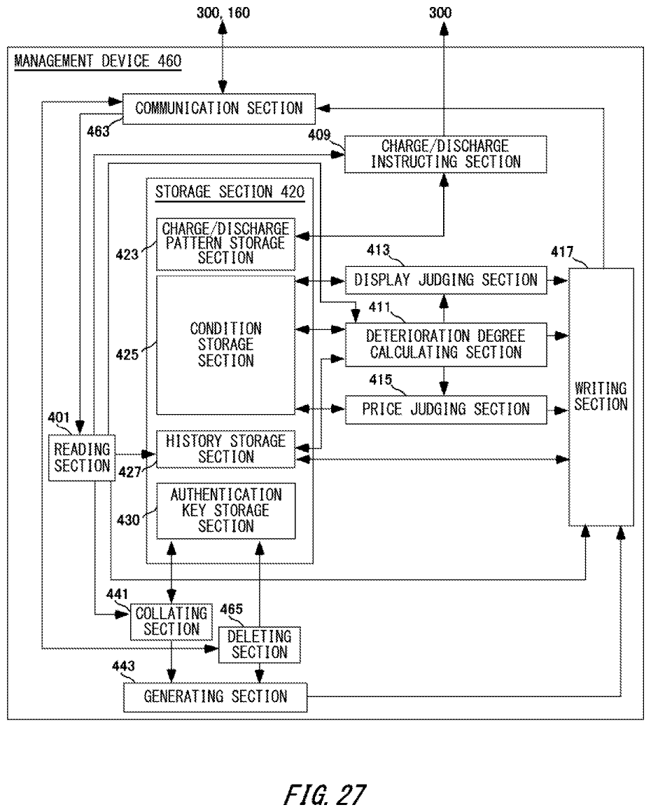

FIG. 27 is a block diagram of the management device 460. In the management device 460, the difference is that the communication section 463 communicates with the vehicle 160, and the deleting section 465 instructs the vehicle 160 to delete the authentication key. Besides, for the same component as the management device 450 in the fifth embodiment, the explanation is omitted.

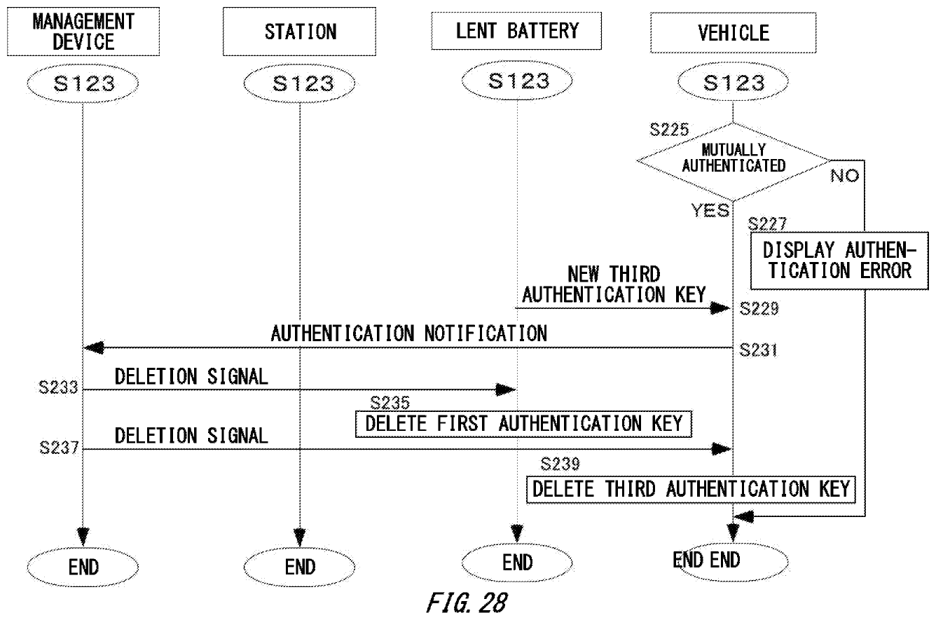

FIG. 28 is a flow diagram of the operation of the management system 21 in the sixth embodiment. FIG. 28 shows a flow of the operation after step S123 in the operation of FIG. 24. If the mutual authentication fails in the collation of step S123 in FIG. 24 (S225: No), the vehicle 160 displays the authentication error on the display section 131 (S227), and the flow ends.

If the mutual authentication succeeds (S225; YES), the vehicle 160 reads and stores the new third authentication key from the battery 250 (S129). The vehicle 160 further transmits the authentication notification indicating that the mutual authentication has succeeded to the management device 460 (S231).

The management device 460 sends, to the battery 250, a deleting signal to delete the old first authentication key when it receives the authentication notification (S233). When the battery 250 receives the deleting signal via the station 300, it deletes the old first authentication key (S235).

Similarly, the management device 460 sends, to the vehicle 160, a deleting signal to delete the old third authentication key when it receives the authentication notification (S237). When the vehicle 160 receives the deleting signal, it deletes the old third authentication key (S239). Then, the flow ends. From the above, the flow in FIG. 28 is performed repeatedly while each device such as management device 460 operates.

The present embodiment has the effect similar to the fifth embodiment. Furthermore, even if the deleting section is not provided on the vehicle 160, the old authentication key of the vehicle 160 and the battery 250 can be deleted.

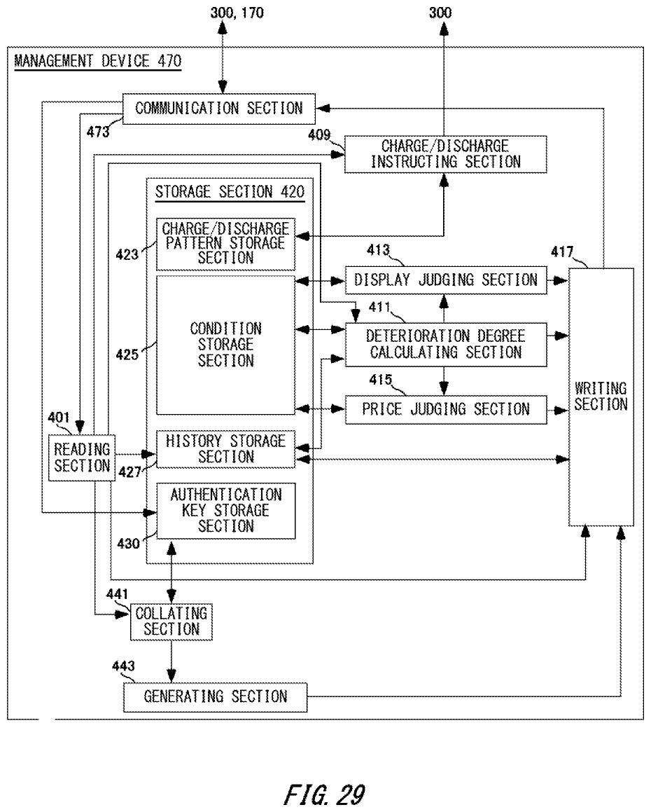

FIG. 29 is a block diagram of the management device 470 in the seventh embodiment. The management device 470 is different from the management device 450 in the fifth embodiment in that it does not have the deleting section 445, and the communication section 473 communicates with the vehicle 170. Besides, for the same component as the management device 450 in the fifth embodiment, the explanation is omitted.

The vehicle 170 is different from the vehicle 150 in the fifth embodiment in that it communicates with the management device 450 and transmits the deleting signal to delete the authentication key to the deleting section 129. Others are the same as that of the vehicle 150 in the fifth embodiment, and the block diagram and the explanation are omitted.

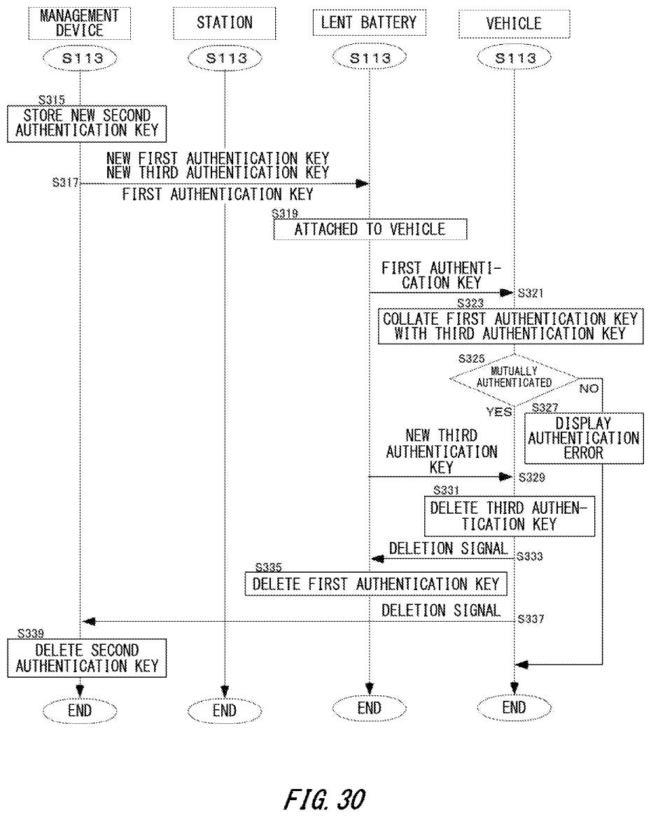

FIG. 30 is a flow diagram of the operation in the seventh embodiment. FIG. 30 shows the flow of the operation after step S113 in the operation in FIG. 24. First, the management device 470 stores a new second authentication key in step S315. However, an old authentication key also remains because the management device 470 does not have a deleting section. Hereinafter, step S317 to S335 are the same as step S117 to S135 in FIG. 24, and the explanation is omitted.

The vehicle 170 sends a deleting signal to the management device 470 (S337) to delete the old second authentication key recorded in the management device 470 (S339) as long as the mutual authentication succeeds in step S325. Then, the flow ends. The flow in FIG. 30 described above is performed repeatedly while each device such as management device 470 operates.

The present embodiment has the effect similar to that of the fifth embodiment. Furthermore, the authentication with the battery 250 succeeds in the vehicle 170, and then the old authentication key of the management device 470 is deleted. Therefore, if the battery 250 is genuine but the authentication between the vehicle 170 and the battery 250 does not succeed for any reason, the operation can be started again from step S107 using the old authentication key.

In the fifth embodiment described above, the management device and the vehicle have a deleting section, in the sixth embodiment only the management device has a deleting section, and in the seventh embodiment only the vehicle has a deleting section. Alternatively, only the battery may have a deleting section.

In this case, the battery may be provided with a collating section, which reads the third authentication key from the vehicle and collates it with the first authentication key of its own. If the collating section succeeds in the authentication, it transmits a new third authentication to the vehicle and the deleting section in the battery deletes the old second authentication key of the vehicle.

Furthermore, the collating section may read the second authentication key from the management device to the battery, and collate it with its own first authentication key. If the collating section succeeds in the authentication, the deleting section of the battery deletes the old second authentication key of the management device.

It is noted that, like other embodiments, if the authentication does not succeed, the reading and writing process of the information on the battery is prohibited.

It is noted that each of the management device, the battery, and the vehicle may have a deleting section. In addition, any of them may not have the deleting section, and a new authentication key may be programmed to delete the old authentication key with any trigger.

In the fifth to seventh embodiment described above, the authentication keys are not particularly limited as long as they can be collated with each other for authentication. For example, the authentication key are character strings, numeric strings, or the combination thereof which are at least partially the same as each other, and the authentication is judged as success when the same part matches each other. The authentication keys may also be numeric strings different from each other, and the authentication may be judged as success when the known solution is derived by performing a particular calculation such as adding values of each digit.

In the fifth to seventh embodiment described above, the management device maintains authentication keys for the management device, whose number corresponds to the number of the lent batteries, generated every time batteries are returned until the batteries are returned. Alternatively, the management device may generate only authentication keys for the battery and the vehicle every time the batteries are returned, retain a common hash value for all authentication keys which are generated, and, at the time of the return of the battery, does not perform the mutual authentication of the authentication key but judge that the battery and the vehicle are genuine by using the authentication key for the battery and the vehicle obtained from the battery, and the hash value.

In the fifth to seventh embodiment described above, because every time the battery is returned to the station the management device newly generates authentication keys which are unique to each of the management device, the battery, and the vehicle and which can be mutually authenticated, the user assumes that battery is to be returned to the same station as the station where the battery is borrowed. However, by delivering a new authentication key generated by one management device to other plurality of management devices so that the new authentication key is shared between the plurality of management devices disposed in different stations, the mutual authentication of the authentication key between the battery and the management device of the different station may be possible even when the user returns the battery to a station different from the station where the battery is borrowed. Also, the management system may additionally include a server to receive a newly generated authentication key from a plurality of management devices and centrally manage them. In this case, if the user returns the battery to a station different from the station where the battery is borrowed, the management device in the different station may query the server to obtain a new authentication key so that the mutual authentication of the authentication key between the battery returned by the user and the management device in the different station is possible.

In the fifth to seventh embodiment described above, every time the battery is returned to the station, the management device newly generates an authentication key which is unique to each of the management device, the battery, and the vehicle and which can be mutually authenticated. Alternatively, during a period starting from a predetermined date and time, for example, a period after 0:00 on January 1 and before 0:00 on January 1 next year, every time a battery is returned to the station, the management device may repeatedly generate one authentication key common to the management device, the battery, and the vehicle, and, after 0:00 on January 1 next year, change it to one new authentication key common to the management device, the battery, and the vehicle, and every time a battery is returned to the station, the management device may repeatedly generate the one new authentication key as in the previous year.

In addition, in the fifth to seventh embodiment described above, the authentication key of a battery may be updated when the battery is returned. In addition, in fifth to seventh embodiment described above, instead of updating the authentication key every time lending the battery, the authentication key may be updated at a predetermined timing. Examples of the predetermined timing include a constant period, the number of times that the authentication succeeds with the authentication key, or the like.

In the fifth to seventh embodiment described above, if a new vehicle is introduced, a battery is lent without a step of returning the battery. Therefore, at the first time that the battery is mounted to the vehicle, the management company preferably controls the vehicle to read a new third authentication key from the battery and store it in the vehicle without performing a collation process in the vehicle. In addition, if the authenticate does not succeed in step S109 or the like in FIG. 24 and a new battery is lent, the similar control may be performed.

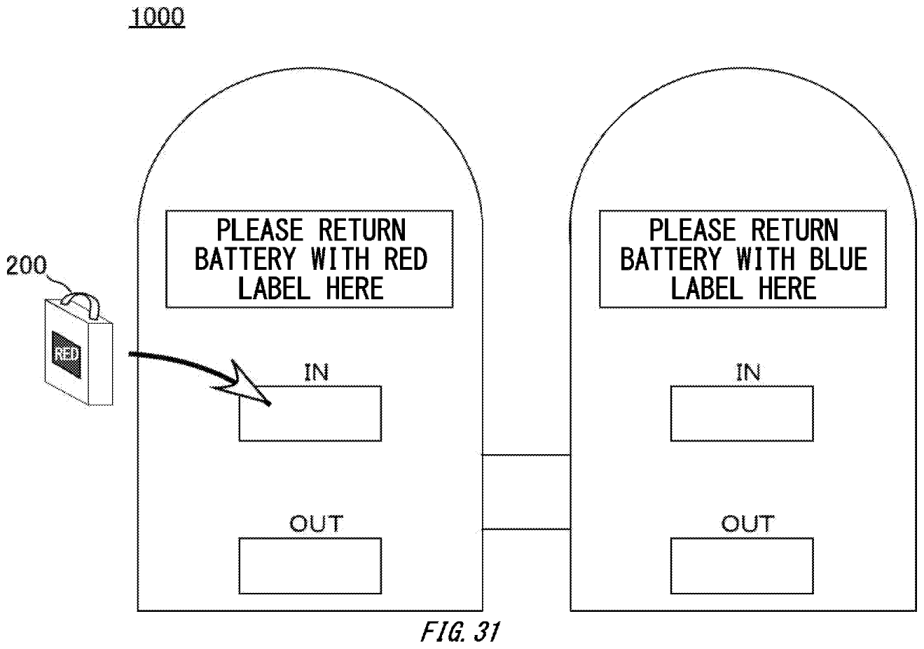

FIG. 31 is a schematic view of the station 1000 as a variant. The station 1000 shown in FIG. 31 is different from the station 300 shown in FIG. 1 in that two accommodating shelves are arranged side by side, the accommodated battery 200 retained in each accommodating shelf can be moved within the station 1000, and conveyance paths are provided between the accommodating shelves so that the battery 200 accommodated in each accommodating shelf can be moved via the conveyance path.

In addition, in each accommodating shelf, one return slot for the battery 200, indicated with “IN”, is disposed, one outlet slot for the battery 200 to be lent, indicated with “OUT”, is disposed, and the battery 200 accommodated in the accommodating shelf is not visible to the user 60 outside.

Furthermore, in the variant, a display is disposed in the upper part of each accommodating shelf, a message of “return the battery with a red label here” is displayed on the display of the accommodating shelf on the left side of the document, a message of “return the battery with a blue label here” is displayed on the display of the accommodating shelf on the right side, the accommodating shelf on the left side of the document is, for example, dedicated for the battery 200 of deterioration class 1 to 3, and the accommodating shelf on the right side is, for example, dedicated for the battery 200 of deterioration class 4 to 5. Thus, in the station 1000, the accommodating shelf of the battery 200 is different depending on the deterioration class and deterioration indication.

In the first embodiment to seventh embodiment described above, the station supplies the electrical power supplied from a substation of an electric power company, to the stocked battery. Additionally, a power generation device which generates electricity from natural energy such as solar ray may be provided on the station to charge the electrical power generated by the power generation device in the stocked battery. In addition, the station may be provided with an emergency battery as a buffer. The emergency battery may be an old battery which cannot be used as a battery for lending due to, for example, a high deterioration degree.

Various embodiments of the present invention may be described with reference to flowcharts and block diagrams whose blocks may represent (1) steps of processes in which operations are performed or (2) sections of devices responsible for performing operations. Certain steps and sections may be implemented by dedicated circuitry, programmable circuitry supplied with computer-readable instructions stored on computer-readable media, and/or processors supplied with computer-readable instructions stored on computer-readable media. Dedicated circuitry may include digital and/or analog hardware circuits and may include integrated circuits (IC) and/or discrete circuits. Programmable circuitry may include reconfigurable hardware circuits comprising logical AND, OR, XOR, NAND, NOR, and other logical operations, flip-flops, registers, memory elements, etc., such as field-programmable gate arrays (FPGA), programmable logic arrays (PLA), etc.

Computer-readable media may include any tangible device that can store instructions for execution by a suitable device, such that the computer-readable medium having instructions stored therein comprises an article of manufacture including instructions which can be executed to create means for performing operations specified in the flowcharts or block diagrams. Examples of computer-readable media may include an electronic storage medium, a magnetic storage medium, an optical storage medium, an electromagnetic storage medium, a semiconductor storage medium, etc. More specific examples of computer-readable media may include a floppy (registered trademark) disk, a diskette, a hard disk, a random access memory (RAM), a read-only memory (ROM), an erasable programmable read-only memory (EPROM or Flash memory), an electrically erasable programmable read-only memory (EEPROM), a static random access memory (SRAM), a compact disc read-only memory (CD-ROM), a digital versatile disk (DVD), a BLU-RAY (registered trademark) disc, a memory stick, an integrated circuit card, etc.

Computer-readable instructions may include assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, JAVA (registered trademark), C++, etc., and conventional procedural programming languages, such as the “C” programming language or similar programming languages.

Computer-readable instructions may be provided to a processor of a general purpose computer, special purpose computer, or other programmable data processing device, or to programmable circuitry, locally or via a local area network (LAN), wide area network (WAN) such as the Internet, etc., to execute the computer-readable instructions to create means for performing operations specified in the flowcharts or block diagrams. Examples of processors include computer processors, processing units, microprocessors, digital signal processors, controllers, microcontrollers, etc.

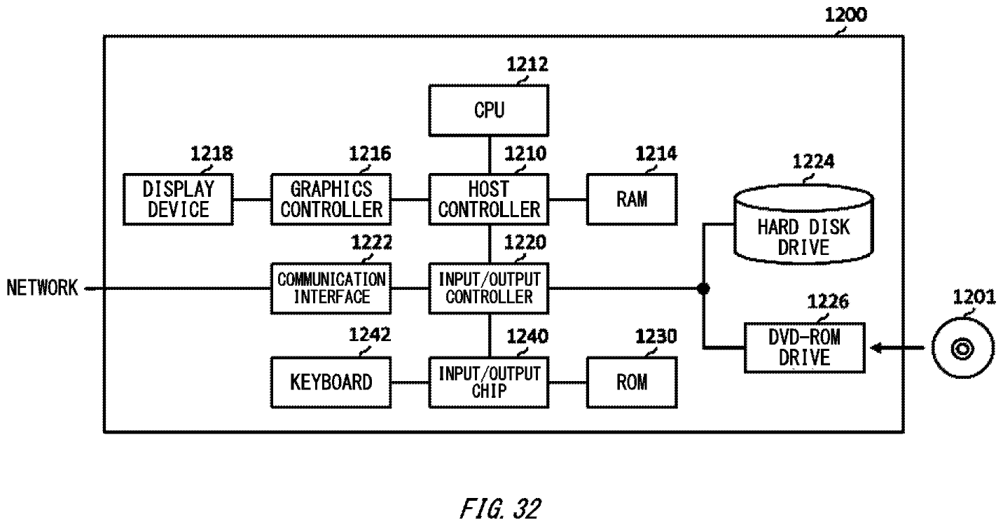

FIG. 32 shows an example of the computer 1200 which can realize a plurality of aspects of the present invention entirely or partially. A program installed on the computer 1200 can cause the computer 1200 to function as an operation associated with a device according to embodiments of the present invention or as one or more “unit(s)” of the device, or to perform the operation or the one or more “unit(s)”, and/or can cause the computer 1200 to perform processes according to embodiments of the present invention or steps of the processes. Such a program may be executed by a CPU 1212 to cause the computer 1200 to perform particular operations associated with some or all blocks in the flowcharts or block diagrams described herein.

The computer 1200 according to the present embodiment includes a CPU 1212, a RAM 1214, a graphics controller 1216 and a display device 1218, which are connected to each other by a host controller 1210. The computer 1200 also includes input/output units such as a communication interface 1222, a hard disk drive 1224, a DVD-ROM drive 1226 and an IC card drive, which are connected to the host controller 1210 via an input/output controller 1220. The computer also includes legacy input/output units such as a ROM 1230 and a keyboard 1242, which are connected to the input/output controller 1220 via an input/output chip 1240.

The CPU 1212 operates in accordance with programs stored in the ROM 1230 and the RAM 1214, and controls each unit accordingly. The graphics controller 1216 acquires image data generated by the CPU 1212 on a frame buffer or the like provided in the RAM 1214 or in the graphics controller 1216 itself, and displays the image data on the display device 1218.

The communication interface 1222 communicates with other electronic devices via a network. The hard disk drive 1224 stores programs and data to be used by the CPU 1212 in the computer 1200. The DVD-ROM drive 1226 reads programs or data from the DVD-ROM 1201, and provides the programs or data to the hard disk drive 1224 via the RAM 1214. The IC card drive reads programs and data from an IC card and/or writes programs and data into the IC card.

The ROM 1230 has stored therein a boot program or the like to be executed by the computer 1200 at the time of activation, and/or a program that depends on the hardware of the computer 1200. The input/output chip 1240 may also connect various input/output units to the input/output controller 1220 via a parallel port, a serial port, a keyboard port, a mouse port or the like.

Programs are provided by a computer-readable storage medium such as the DVD-ROM 1201 or an IC card. The programs are read from the computer-readable storage medium, installed on the hard disk drive 1224, the RAM 1214 or the ROM 1230, which are also examples of a computer-readable storage medium, and executed by the CPU 1212. The information processing described in the programs is read into the computer 1200, resulting in cooperation between the programs and the above various types of hardware resources. A device or method may be constituted by implementing the operation or processing of information in accordance with the use of the computer 1200.

For example, if a communication is performed between the computer 1200 and external devices, the CPU 1212 may execute a communication program loaded on the RAM 1214, and instruct the communication interface 1222 to perform communication process based on the process described in the communication program. Under the control of the CPU 1212, the communication interface 1222 reads transmission data stored in a transmission buffer region provided in a recording medium such as the RAM 1214, the hard disk drive 1224, the DVD-ROM 1201 or an IC card, and sends the read transmission data to the network, or writes reception data received from the network into a reception buffer region or the like provided in the recording medium.

The CPU 1212 may also make all or required portions of the files or databases stored in an external recording medium such as the hard disk drive 1224, the DVD-ROM drive 1226 (DVD-ROM 1201) or an IC card to be read by the RAM 1214, and perform various types of processing on the data on the RAM 1214. Then, the CPU 1212 may write back the processed data to the external recording medium.

Various types of information such as various types of programs, data, tables and databases may be stored in the recording medium for information processing. The CPU 1212 may perform various types of processing on the data read from the RAM 1214, which includes various types of operations, information processing, condition judging, conditional branch, unconditional branch, search/replacement of information, etc., as described throughout this disclosure and specified by an instruction sequence of programs, and writes the result back to the RAM 1214. In addition, the CPU 1212 may search for information in a file, a database, etc., in the recording medium. For example, when a plurality of entries, each having an attribute value of a first attribute associated with an attribute value of a second attribute, are stored in the recording medium, the CPU 1212 may search the plurality of entries for an entry whose attribute value of the first attribute matches a designated condition, read the attribute value of the second attribute stored in the entry, and thereby acquire the attribute value of the second attribute associated with the first attribute that meets a predetermined condition.

The programs or software modules in the above description may be stored on the computer 1200 or a computer-readable storage medium near the computer 1200. Further, a recording medium such as a hard disk or a RAM provided in a server system connected to a dedicated communication network or the Internet can be used as a computer-readable storage media, which provides programs to the computer 1200 via the network.

While the embodiments of the present invention have been described, the technical scope of the invention is not limited to the above described embodiments. It is apparent to persons skilled in the art that various alterations or improvements can be added to the above-described embodiments. Also, matters explained with reference to a particular embodiment can be applied to other embodiments as long as such application does not cause a technical contradiction. Also, each component may have similar features to another component having the same name and a different reference numeral. It is also apparent from the scope of the claims that the embodiments added with such alterations or improvements can be included in the technical scope of the invention.

The operations, procedures, steps, and stages of each process performed by a device, system, program, and method shown in the claims, specification, or diagrams can be performed in any order as long as the order is not indicated by “prior to,” “before,” or the like and as long as the output from a previous process is not used in a later process. Even if the process flow is described using phrases such as “first” or “next” in the claims, specification, or diagrams, it does not necessarily mean that the process must be performed in this order.

### EXPLANATION OF REFERENCES

19, 20, 21 management system
40 communication network
60 user
100, 150, 160, 170 vehicle
101 battery-accommodating section
102, 162 communication section
103 charge/discharge amount measuring section
105 SOC calculating section
107 battery temperature measuring section
109 regenerative electric power charge section
111 location-information obtaining section
112 date and time measuring section
113 acceleration measuring section
115 travel time measuring section
117 travel distance measuring section
119 driving disposition judging section
120 storage section
121 condition storage section
122 user-related information storage section
123 vehicle ID storage section
124 authentication key storage section
125 writing section
126 vehicle-related information storage section
127 collating section
129 deleting section
131 display section
200, 250, 800 battery
210, 810 storage section
211 usage history information storage section
213, 813 driving history storage section
215, 815 usage situation history storage section
217, 817 battery information storage section
218 authentication key storage section
219, 819 related information storage section
221, 821 user-related information storage section
223, 823 vehicle-related information storage section
230 communication section
240, 840 deterioration displaying section
825 condition storage section
850 measuring section
861 deterioration degree calculating section
865 price judging section
300 station
301 battery-accommodating section
303 read/write section
305 charge/discharge section
307 display section
309 input section
400, 450, 460, 470, 600, 900 management device
401, 601, 901 reading section
403, 463, 473, 603, 903 communication section
405, 905 presenting section
407, 607, 907 lending processing section
409, 609, 909 charge/discharge instructing section
411 deterioration degree calculating section
412, 912 location output section
413 display judging section
414, 914 good return reward section
415 price judging section
416, 916 good usage reward section
417, 617, 917 writing section
419, 619, 919 management section
420, 620, 920 storage section
421, 921 identifying information storage section
423, 623, 923 charge/discharge pattern storage section
425, 925 condition storage section
427, 927 history storage section
429, 629, 929 ID list storage section
430 authentication key storage section
431, 631, 931 related information storage section
433, 633, 933 address distance storage section
435, 635, 935 area information storage section
437, 937 reward information storage section
441 collating section
443 generating section
445, 465 deleting section
500, 700 server
501, 701 communication section
509, 709 management section
510, 710 storage section
517, 717 related information storage section
705 presenting section
711 deterioration degree calculating section
712 location output section
713 display judging section
714 good return reward section
715 price judging section
716 good usage reward section
721 identifying information storage section
725 condition storage section
727 history storage section
737 reward information storage section
812 accumulated usage history information storage section
1200 computer
1201 DVD-ROM
1210 host controller
1212 CPU
1214 RAM
1216 graphics controller
1218 display device
1220 input/output controller
1222 communication interface
1224 hard disk drive
1226 DVD-ROM drive
1230 ROM
1240 input/output chip
1242 keyboard

What is claimed is:

1. A battery which is detachable to an electrically driven vehicle, the battery comprising:
a deterioration displaying section which is configured to display, visibly from an outside, a deterioration degree indicating a degree of a deterioration of the battery at a present time regardless of a charge amount of the battery at a present time.

2. The battery according to claim 1, wherein
the deterioration displaying section is configured to display, visibly from an outside, a deterioration class indicating a deterioration degree of the battery at a present time in a stepwise manner.

3. The battery according to claim 2, further comprising:
a storage section which is configured to store usage history information indicating how the battery has been used in the vehicle and further store a deterioration class condition to judge a deterioration class of the battery based on a deterioration degree of the battery; and
a calculating section which is configured to calculate a deterioration degree of the battery based on the usage history information stored in the storage section, judge a deterioration class of the battery based on the calculated deterioration degree of the battery in reference to the deterioration class condition, and output the deterioration class to the deterioration displaying section.

4. The battery according to claim 3, wherein
the usage history information includes at least any of driving history information indicating a driving history of the vehicle and usage situation history information indicating a history of usage situation of the battery.

5. The battery according to claim 1, further comprising:
a storage section which is configured to store usage history information indicating how the battery has been used in the vehicle and further store a price condition to judge a price of the battery based on a deterioration degree of the battery; and
a calculating section which is configured to calculate a deterioration degree of the battery based on the usage history information stored in the storage section, judge a price of the battery based on the calculated deterioration degree of the battery in reference to the price condition, and output the price to the deterioration displaying section, wherein
the deterioration displaying section is configured to display, visibly to an outside, a price of the battery calculated by the calculating section.

6. The battery according to claim 3, wherein
the storage section is configured to store a price condition to judge a price of the battery based on at least one of a deterioration degree of the battery and a deterioration class of the battery,
the calculating section is configured to judge a price of the battery based on at least one of a deterioration degree of the battery and a deterioration class of the battery in reference to the price condition and output the price to the deterioration displaying section, and
the deterioration displaying section is configured to display, visibly to an outside, a price of the battery calculated by the calculating section.
